(19) United States
(12) Patent Application Publication
(10) Pub. No.: US 2026/0239911 A1
(43) Pub. Date: Aug. 13, 2026

(54) SUBSTRATE PROCESSING APPARATUS AND METHOD OF MAINTAINING DRYING DEVICE IN SUBSTRATE PROCESSING APPARATUS

(71) Applicant: Tokyo Electron Limited, Tokyo (JP)

(72) Inventors: Shota Umezaki, Koshi City (JP); Takahiro Hayashida, Koshi City (JP); Mikio Nakashima, Koshi City (JP); Takafumi Yasunaga, Koshi City (JP)

(73) Assignee: Tokyo Electron Limited, Tokyo (JP)

(21) Appl. No.: 19/645,671

(22) Filed: Apr. 13, 2026

Related U.S. Application Data
(63) Continuation of application No. 18/412,768, filed on Jan. 15, 2024, now Pat. No. 12,622,200.

(30) Foreign Application Priority Data
Jan. 17, 2023 (JP) 2023-004940

(51) Int. Cl. H10P 72/00

(52) U.S. Cl. CPC H10P 72/0404; H10P 72/0454; H10P 72/0464

(57) ABSTRACT

A substrate processing apparatus includes a unit block including multiple liquid film forming devices each configured to form a liquid film on a top surface of a substrate, and a drying device configured to replace the liquid film with a supercritical fluid to dry the substrate; and a transfer block provided between the multiple liquid film forming devices and the drying device. The transfer block includes a transfer device configured to transfer the substrate between the multiple liquid film forming devices and the drying device, and a length of a transfer path of the substrate is equal between each of the multiple liquid film forming devices and the drying device.

### CROSS-REFERENCE TO RELATED APPLICATION

This is a continuation application of U.S. Patent Application No. 18/412,768, filed on January 15, 2024, which claims the benefit of Japanese Patent Application No. 2023-004940, filed on January 17, 2023, the entire disclosures of which are incorporated herein by reference.

### TECHNICAL FIELD

The various aspects and embodiments described herein pertain generally to a substrate processing apparatus and a substrate processing method.

### BACKGROUND

There is known a technique of drying a substrate by using a supercritical fluid. Patent Document 1 discloses an apparatus having multiple sets of liquid film forming units and drying units. The drying unit dries the substrate by replacing the liquid film formed on a top surface of the substrate in the liquid film forming unit with the supercritical fluid.

Patent Document 1: Japanese Patent Laid-open Publication No. 2022-030851

### SUMMARY

In one exemplary embodiment, a substrate processing apparatus includes a unit block including multiple liquid film forming devices each configured to form a liquid film on a top surface of a substrate, and a drying device configured to replace the liquid film with a supercritical fluid to dry the substrate; and a transfer block provided between the multiple liquid film forming devices and the drying device. The transfer block includes a transfer device configured to transfer the substrate between the multiple liquid film forming devices and the drying device, and a length of a transfer path of the substrate is equal between each of the multiple liquid film forming devices and the drying device.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view of a substrate processing apparatus according to an exemplary embodiment;

FIG. 2 is a front view of the substrate processing apparatus according to the exemplary embodiment;

FIG. 3 is a side view of the substrate processing apparatus according to the exemplary embodiment;

FIG. 4 is a timing chart showing a substrate processing method according to the exemplary embodiment;

FIG. 5 is a plan view showing the substrate processing method according to the exemplary embodiment;

FIG. 6 is a plan view showing the substrate processing method according to the exemplary embodiment;

FIG. 7 is a plan view showing the substrate processing method according to the exemplary embodiment;

FIG. 8 is a plan view showing the substrate processing method according to the exemplary embodiment;

FIG. 9 is a plan view showing the substrate processing method according to the exemplary embodiment;

FIG. 10 is a plan view showing the substrate processing method according to the exemplary embodiment;

FIG. 11 is a plan view showing the substrate processing method according to the exemplary embodiment;

FIG. 12 is a plan view showing the substrate processing method according to the exemplary embodiment;

FIG. 13 is a plan view showing the substrate processing method according to the exemplary embodiment;

FIG. 14 is a plan view showing the substrate processing method according to the exemplary embodiment:

FIG. 15 is a plan view showing the substrate processing method according to the exemplary embodiment;

FIG. 16 is a plan view showing the substrate processing method according to the exemplary embodiment;

FIG. 17 is a plan view showing the substrate processing method according to the exemplary embodiment;

FIG. 18 is a plan view showing the substrate processing method according to the exemplary embodiment;

FIG. 19 is a plan view showing the substrate processing method according to the exemplary embodiment;

FIG. 20 is a plan view showing the substrate processing method according to the exemplary embodiment;

FIG. 21 is a plan view showing the substrate processing method according to the exemplary embodiment;

FIG. 22 is a plan view showing the substrate processing method according to the exemplary embodiment;

FIG. 23A and FIG. 23B are diagrams showing an intermediate area when a device is in operation;

FIG. 24A and FIG. 24B are diagrams showing the intermediate area during maintenance of a lower level;

FIG. 25A and FIG. 25B are diagrams showing the intermediate area during maintenance of intermediate and upper levels;

FIG. 26 is a plan view of a substrate processing apparatus according to a first modification example of the exemplary embodiment;

FIG. 27 is a plan view of a substrate processing apparatus according to a second modification example of the exemplary embodiment;

FIG. 28 is a plan view of a substrate processing apparatus according to a third modification example of the exemplary embodiment;

FIG. 29 is a plan view of a substrate processing apparatus according to a fourth modification example of the exemplary embodiment;

FIG. 30 is a perspective view illustrating an electrical equipment block;

FIG. 31 is a side view illustrating the electrical equipment block;

FIG. 32A to FIG. 32C are side views illustrating movements of electrical equipment boxes during the maintenance of the lower level;

FIG. 33A and FIG. 33B are side views illustrating movements of the electrical equipment boxes during the maintenance of the intermediate level; and

FIG. 34A to FIG. 34C are side views illustrating movements of the electrical equipment boxes during the maintenance of the upper level.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, non-limiting exemplary embodiments of the present disclosure will be described with reference to the accompanying drawings. In the various drawings, same or corresponding parts will be assigned same or corresponding reference numerals, and redundant description thereof will be omitted. In the present specification, the X-axis direction, the Y-axis direction, and the Z-axis direction are orthogonal to each other. The X-axis direction and Y-axis direction are horizontal directions, whereas the Z-axis direction is a vertical direction.

### Substrate processing apparatus

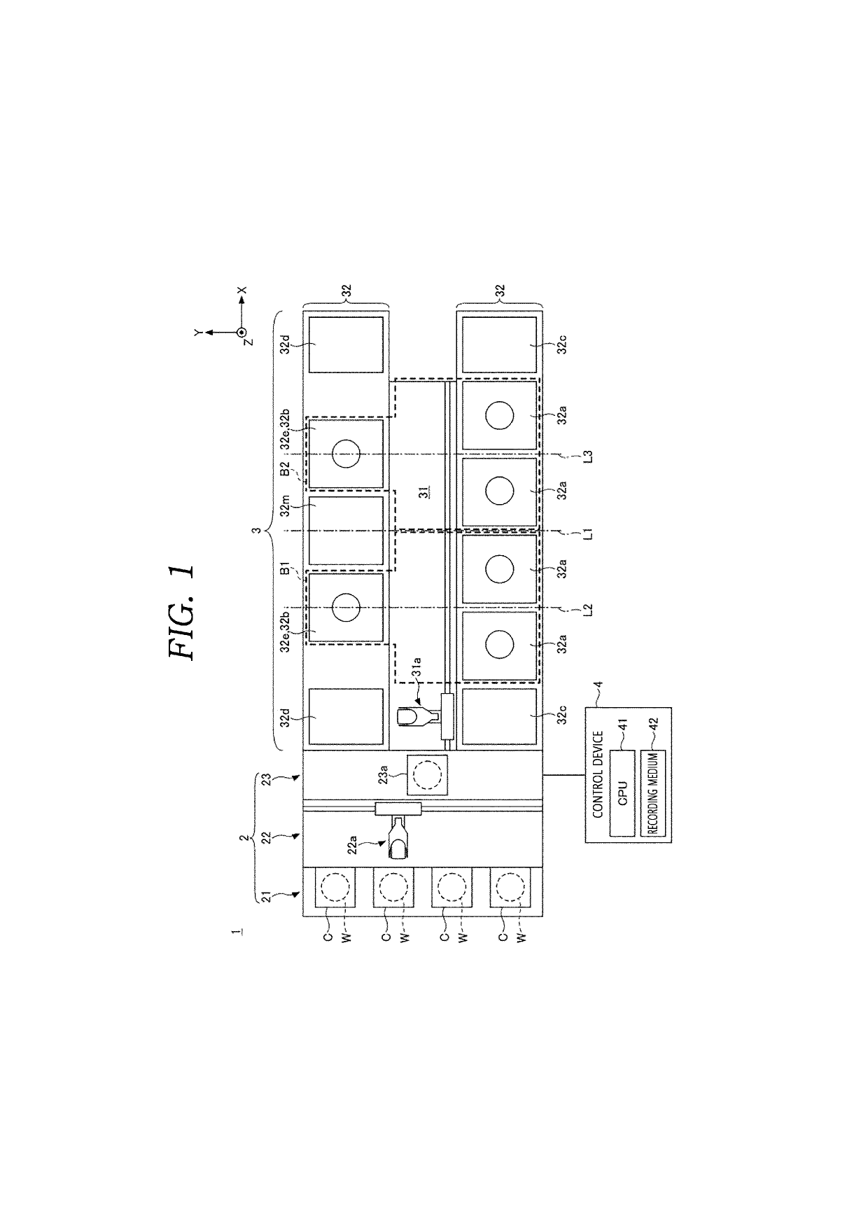

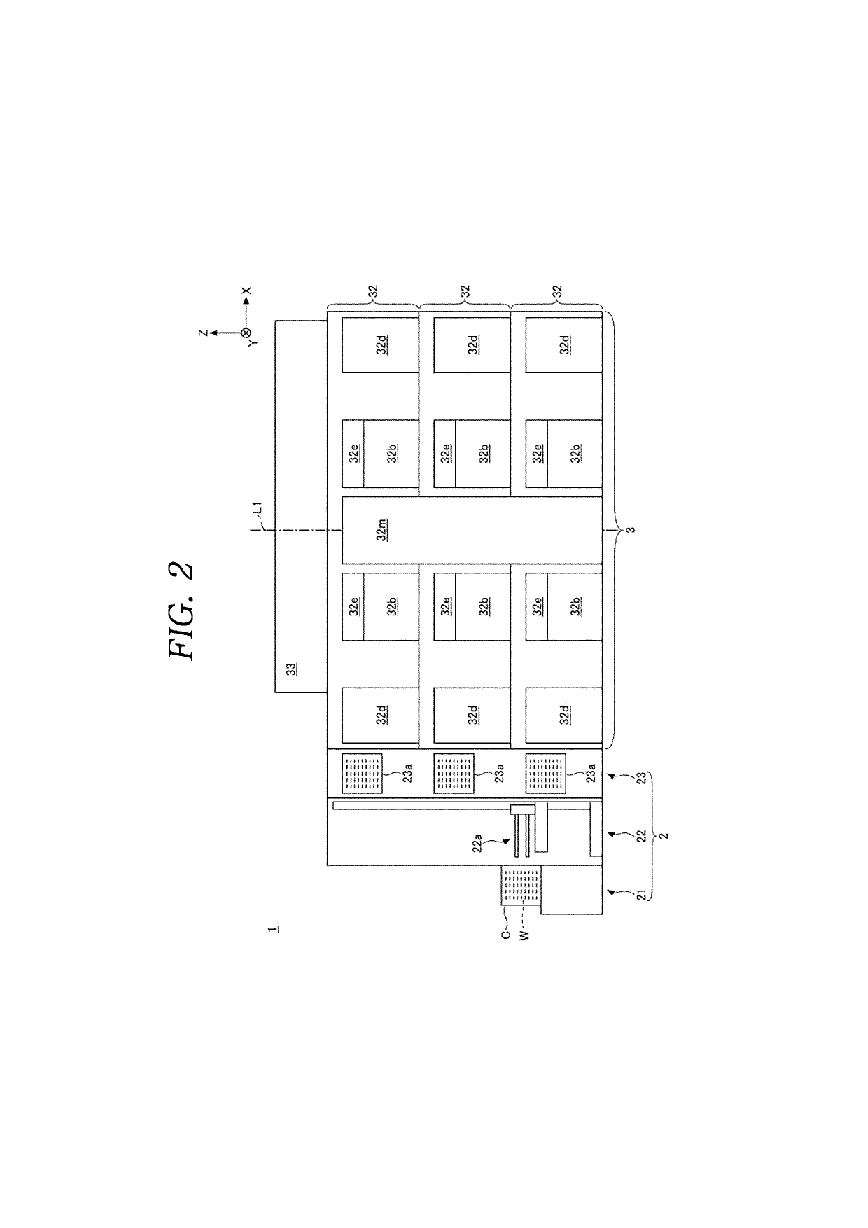

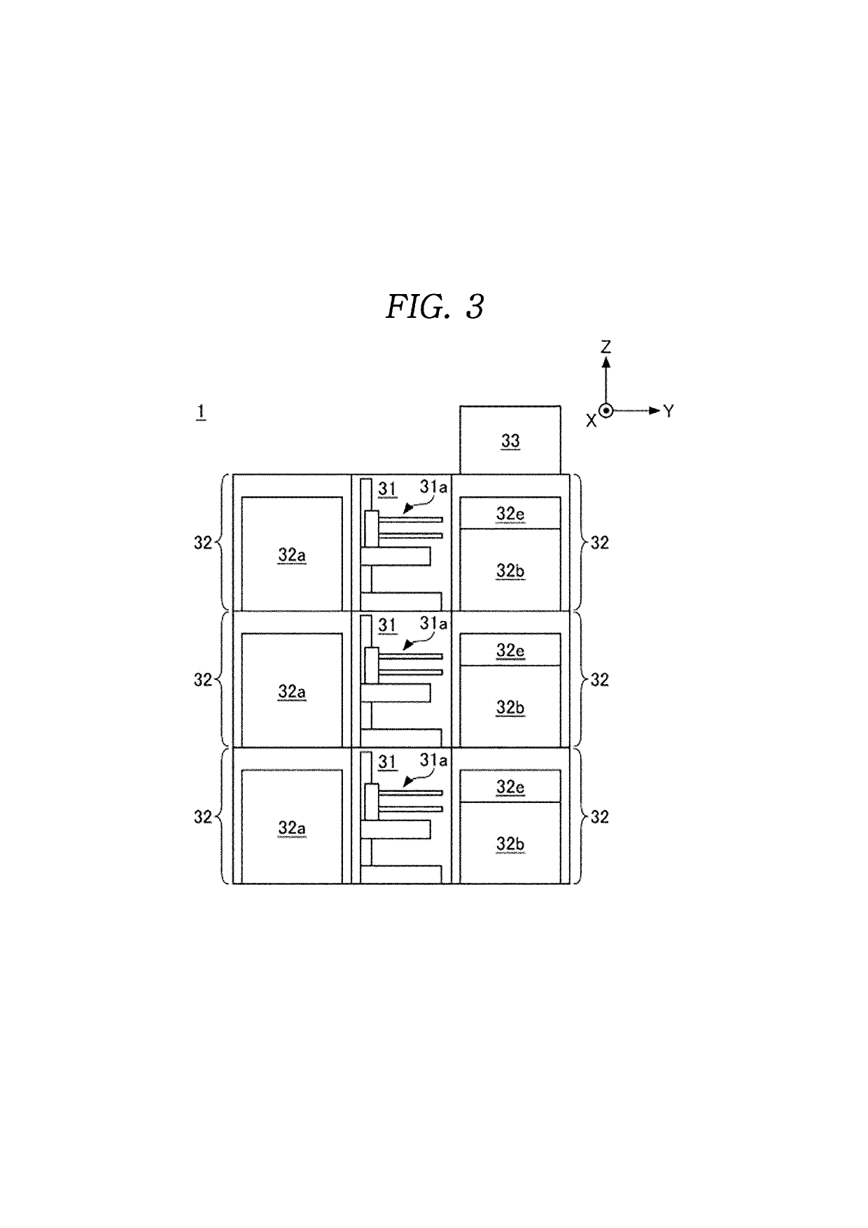

Referring to FIG. 1 to FIG. 3, a substrate processing apparatus 1 according to an exemplary embodiment will be explained. FIG. 1 is a plan view of the substrate processing apparatus 1 according to the exemplary embodiment. FIG. 2 is a front view of the substrate processing apparatus 1 according to the exemplary embodiment. FIG. 3 is a side view of the substrate processing apparatus according to the exemplary embodiment.

The substrate processing apparatus 1 is equipped with a carry-in/out station 2 and a processing station 3. The carry-in/out station 2 and the processing station 3 are provided adjacent to each other in the X-axis direction.

The carry-in/out station 2 is equipped with a placing table 21, a transfer section 22, and a delivery section 23. A plurality of carriers C is placed on the placing table 21. Each of these carriers C accommodates therein a multiple number of substrates W horizontally while maintaining a regular distance between the substrates W in a vertical direction.

The substrate W may include a semiconductor substrate such as a silicon wafer or a compound semiconductor wafer, or a glass substrate. The substrate W may further include a device such as an electronic circuit formed on a surface of the semiconductor substrate or the glass substrate. The substrate W may have an irregularity pattern on the surface thereof.

The transfer section 22 is provided adjacent to the placing table 21. A first transfer device 22a is disposed within the transfer section 22. The first transfer device 22a is configured to transfer the substrate W within the transfer section 22 and transfer the substrate W to/from a plurality of apparatuses disposed next to the transfer section 22.

The first transfer device 22a includes a first transfer arm configured to hold the substrate W. The first transfer arm is movable in horizontal directions (both the X-axis direction and the Y-axis direction) and the vertical direction, and is pivotable around a vertical axis. The number of the first transfer arm may be one or more.

The delivery section 23 is provided adjacent to the transfer section 22. The delivery section 23 includes a transition device 23a configured to accommodate therein the substrate W temporarily. As illustrated in FIG. 2, a plurality of transition devices 23a may be stacked in the vertical direction. Here, the layout and the number of the transition devices 23a are not particularly limited.

The processing station 3 is equipped with a transfer block 31, a plurality of processing blocks 32, and an electrical equipment block 33.

The transfer block 31 is provided adjacent to the delivery section 23. The transfer block 31 is of a rectangular parallelepiped shape. A second transfer device 31a is disposed within the transfer block 31.

The second transfer device 31a is configured to transfer the substrate W between a plurality of apparatuses disposed next to the transfer block 31. The second transfer device 31a includes a second transfer arm configured to hold the substrate W. The second transfer arm is movable in the horizontal directions (both the X-axis direction and the Y-axis direction) and the vertical direction, and is pivotable around a vertical axis. The number of the second transfer arm may be one or more.

The plurality of processing blocks 32 are arranged on both sides of the transfer block 31 in the Y-axis direction. Each processing block 32 is disposed adjacent to the transfer block 31. As shown in FIG. 2, the plurality of processing blocks 32 are stacked on top of each other in the vertical direction. In this case, the footprint of the processing blocks 32 can be reduced. However, the layout and the number of the processing blocks 32 are not particularly limited. When the plurality of processing blocks 32 are stacked in multiple levels in the vertical direction, a plurality of transfer blocks 31 may also be stacked in multiple levels in the vertical direction as shown in FIG. 3. The number of the levels of the transfer blocks 31 and the number of the levels of the processing blocks 32 are equal. Multiple substrates W can be transferred simultaneously at different heights, so that the number of the substrates W processed per unit time can be increased. However, the layout and the number of the transfer blocks 31 are not particularly limited.

The plurality of processing blocks 32 include liquid film forming devices 32a, drying devices 32b, supplying devices 32c and 32d, inspecting devices 32e, and an intermediate area 32m.

Four liquid film forming devices 32a are provided in the processing block 32 located on the negative Y-axis side when viewed from the top. The four liquid film forming devices 32a are arranged along the X-axis direction. The four liquid film forming devices 32a are disposed adjacent to each other. Each liquid film forming device 32a is in contact with the long side of the rectangular transfer block 31. The two liquid film forming devices 32a located on the negative X-axis side and the two liquid film forming devices 32a located on the positive X-axis side are configured to be axisymmetric about a virtual line L1.

The liquid film forming device 32a includes, for example, a spin chuck configured to hold the substrate W horizontally, and a nozzle configured to discharge a liquid onto a top surface of the substrate W. The nozzle supplies the liquid to a center of the top surface of the substrate W being rotated. The liquid is diffused from the center of the top surface of the substrate W toward a periphery thereof due to a centrifugal force. As an example of the liquid, a chemical liquid, a rinse liquid, and drying liquid are supplied in this order. Multiple kinds of chemical liquids may be supplied, and the rinse liquid may also be supplied between the supply of one chemical liquid and the supply of another chemical liquid.

For example, the liquid film forming device 32a forms a liquid film of a chemical liquid on the top surface of the substrate W which is held horizontally, then replaces the liquid film of the chemical liquid with a liquid film of a rinse liquid, and then replaces the liquid film of the rinse liquid with a liquid film of a drying liquid. The chemical liquid is, for example, SC1 (an aqueous solution of ammonia and hydrogen peroxide), dilute hydrofluoric acid (DHF), or the like. The rinse liquid is, for example, deionized water (DIW). The drying liquid is, for example, an organic solvent such as isopropyl alcohol (IPA).

Two drying devices 32b are provided in the processing block 32 that is located on the positive Y-axis side when viewed from the top. The two drying devices 32b are disposed along the X-axis direction. Each drying device 32b is in contact with the long side of the rectangular transfer block 31. The two drying devices 32b are provided to be axisymmetric about the virtual line L1. The two drying devices 32b are arranged with the intermediate area 32m therebetween.

The drying device 32b replaces the liquid film formed on the top surface of the horizontal substrate W with a supercritical fluid to dry the substrate W. The supercritical fluid is a fluid that has a temperature above a critical temperature and a pressure above a critical pressure, and is a fluid in a state in which it is indistinguishable whether it is a liquid or a gas. By replacing the liquid film of the dry liquid or the like with the supercritical fluid, collapse of the irregularity pattern of the substrate W due to a surface tension can be suppressed.

The supply devices 32c are provided on the negative Y-axis side of the transfer block 31. The supply devices 32c are disposed on both sides of the four liquid film forming devices 32a in the X-axis direction. The supply device 32c located on the negative X-axis side is configured to supply a fluid to the two liquid film forming devices 32a located on the negative X-axis side, for example. The supply device 32c located on the positive X-axis side is configured to supply a fluid to the two liquid film forming devices 32a located on the positive X-axis side, for example. Each supply device 32c may or may not be adjacent to the transfer block 31. This is because the substrate W is not carried to or from the supply devices 32c.

The supply device 32c is equipped with a supply device group including a flowmeter, a flow rate controller, a backpressure valve, a heater, and so forth; and a housing that accommodates the supply device group. The supply device 32c supplies a chemical liquid, a rinse liquid, and a drying liquid to the liquid film forming device 32a as an example of the fluid.

The supply devices 32d are provided on the positive Y-axis side of the transfer block 31. The supply devices 32d are disposed on both sides of the two drying devices 32b in the X-axis direction. Each supply device 32d supplies a fluid to the neighboring drying device 32b. Each supply device 32d may or may not be adjacent to the transfer block 31. This is because the substrate W is not carried to or from the supply device 32d.

The supply device 32d is equipped with a supply device group including a flowmeter, a flow rate controller, a backpressure valve, a heater, and so forth, and a housing that accommodates the supply device group. The supply device 32d supplies, for example, CO₂ as the fluid to the drying device 32b.

The inspecting device 32e is disposed on top of the drying device 32b. Alternatively, the inspecting device 32e may be disposed under the drying device 32b. The inspecting device 32e and the drying devices 32b are stacked on top of each other in the vertical direction. In this case, the footprint of the processing block 32 can be reduced.

The inspecting device 32e is configured to inspect a coating state of the substrate W covered by the liquid film. The inspecting device 32e includes, for example, a weight scale, and measures the weight of the substrate W to confirm that the irregularity pattern of the substrate W is covered with the liquid film. The inspecting device 32e may include a film thickness gauge.

The intermediate area 32m is provided between the two drying devices 32b. The intermediate area 32m lies on the virtual line L1. The intermediate area 32m is a maintenance area for an operator to maintain the two drying devices 32b.

The electrical equipment block 33 is disposed on top of the processing blocks 32 that are stacked in multiple levels. The electrical equipment block 33 may be disposed on the positive Y-axis side, for example, as illustrated in FIG. 3. The electrical equipment block 33 may be disposed along the X-axis direction, as shown in FIG. 2. The electrical equipment block 33 includes an electronic control device group configured to control the operation of the drying device 32b, and a housing that accommodates the electronic control device group.

The processing station 3 has a first unit block B1 and a second unit block B2. The first unit block B1 and the second unit block B2 are provided adjacent to each other along the X-axis direction. The first unit block B1 and the second unit block B2 are provided to be axisymmetric about the virtual line L1. Each of the first unit block B1 and the second unit block B2 may be stacked on top of each other. The processing station 3 may have only the first unit block B1 without having the second unit block B2. The processing station 3 may have three or more unit blocks along the X-axis direction.

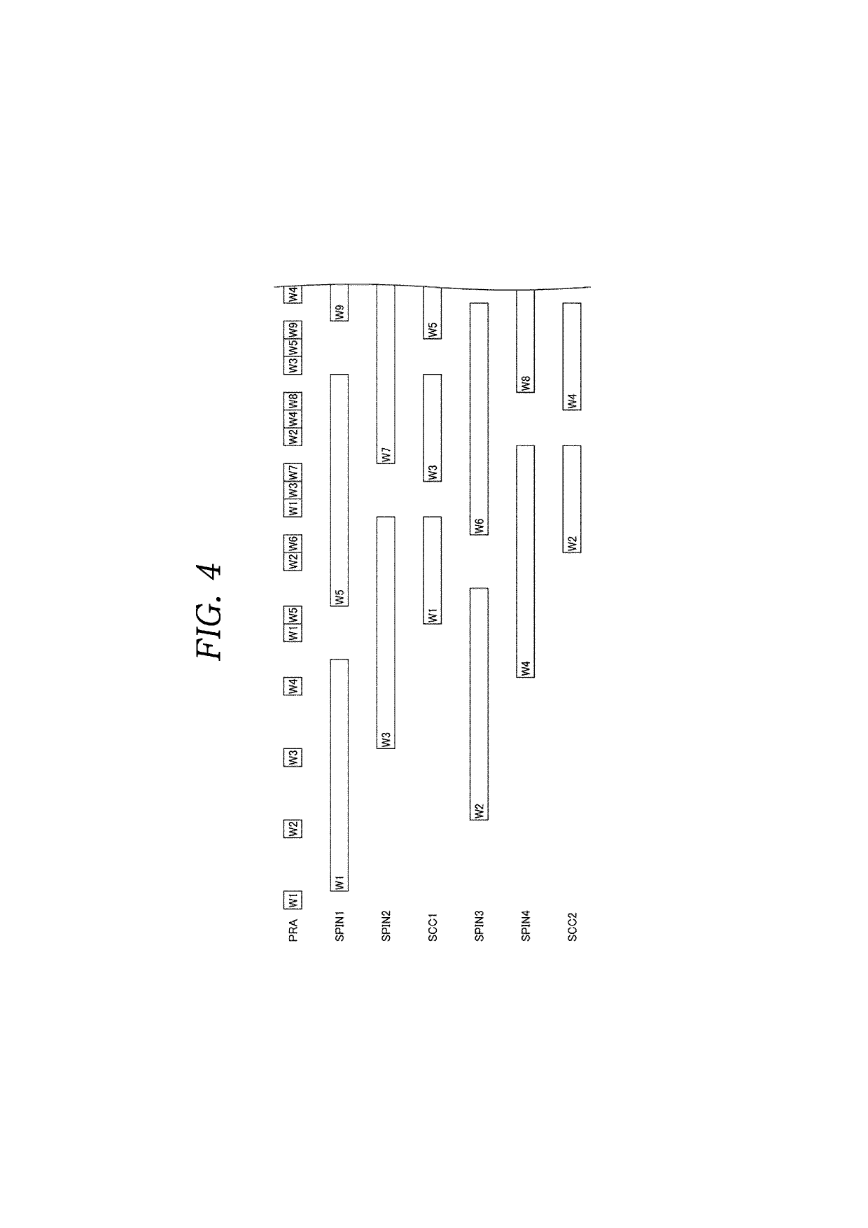

The first unit block B1 includes the two liquid film forming devices 32a and the drying device 32b located on the negative X-axis side with respect to the imaginary line L1 when viewed from the top. The reason for combining one drying device 32b and a plurality of liquid film forming devices 32a is that the time required to process the substrate W in the liquid film forming device 32a is longer than the time taken to process the substrate W in the drying device 32b (see FIG. 4). The two liquid film forming devices 32a are disposed to be axisymmetric about a virtual line L2. The drying devices 32b has its center on the virtual line L2. In this case, a length of a transfer path of the substrate W becomes equal between each of the two liquid film forming devices 32a and the drying device 32b. Accordingly, the time taken until the liquid film formed on the top surface of the substrate W in each of the two liquid film forming device 32a is replaced with the supercritical fluid in the drying device 32b can be made equal. As a result, non-uniformity in processing quality of the substrates W processed in the respective liquid film forming devices 32a can be reduced.

The second unit block B2 includes the two liquid film forming devices 32a and the drying device 32b located on the positive X-axis side with respect to the imaginary line L1 when viewed from the top. The two liquid film forming devices 32a are disposed to be axisymmetric around the virtual line L3. The drying device 32b has its center on the virtual line L3. In this case, the length of the transfer path of the substrate W becomes equal between each of the two liquid film forming devices 32a and the drying device 32b. Accordingly, the time taken until the liquid film formed on the top surface of the substrate W in each of the two liquid film forming devices 32a is replaced with the supercritical fluid in the drying device 32b can be made equal. As a result, the non-uniformity in processing quality of the substrates W processed in the respective liquid film forming devices 32a can be reduced.

When viewed from the top, the intermediate area 32m is provided between the drying device 32b belonging to the first unit block B1 and the drying device 32b belonging to the second unit block B2 for maintenance of both drying devices 32b.

The substrate processing device 1 has a control device 4. The control device 4 is, for example, a computer, and includes a CPU (Central Processing Unit) 41 and a recording medium 42 such as a memory. The recording medium 42 stores therein a program that controls various processings performed in the substrate processing apparatus 1. The control device 4 controls an operation of the substrate processing apparatus 1 by causing the CPU 41 to execute the program stored in the recording medium 42.

### Substrate processing method

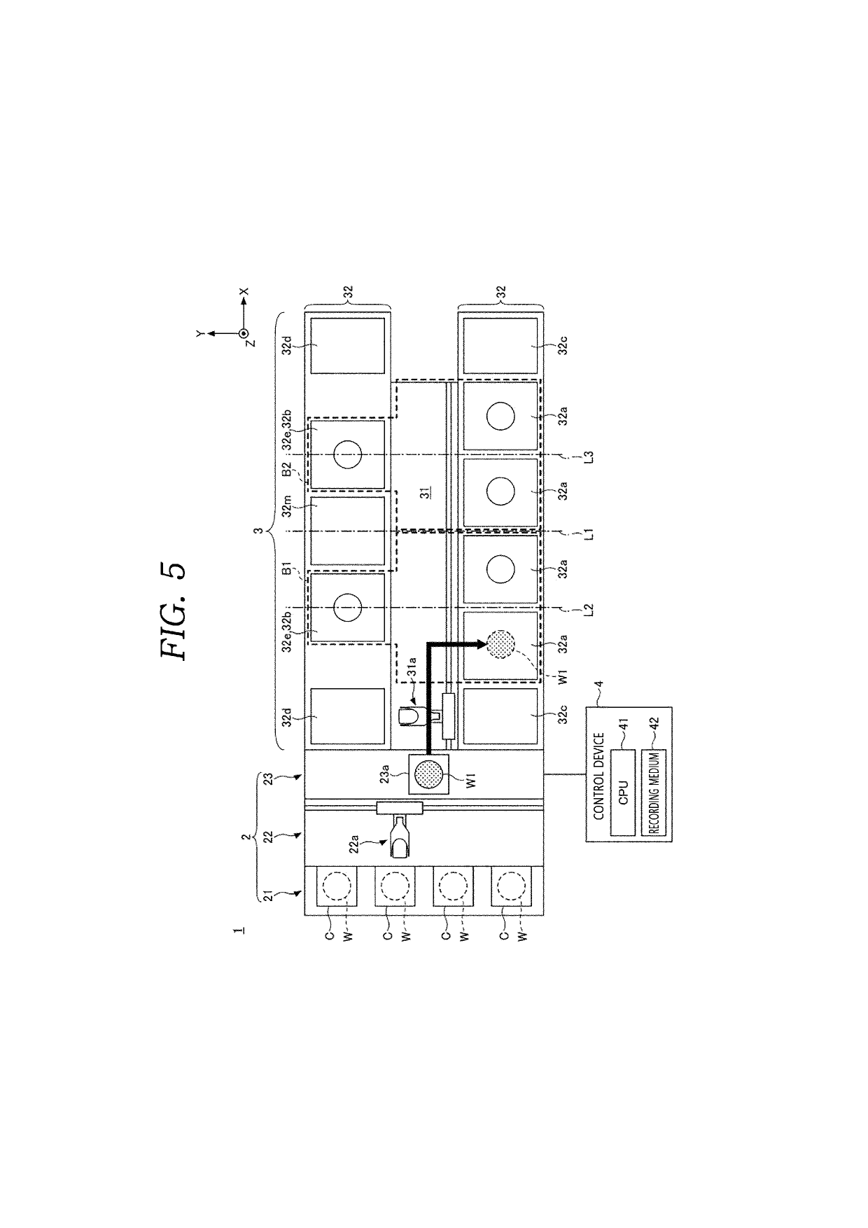

With reference to FIG. 4 to FIG. 22, a substrate processing method according to the exemplary embodiment will be described. FIG. 4 is a timing chart showing the substrate processing method according to the exemplary embodiment. FIG. 4 presents transfer timings for a plurality of substrates W1 to W9 when a substrate processing is performed continually on these substrates W1 to W9. FIG. 5 to FIG. 22 are plan views showing the substrate processing method according to the exemplary embodiment. The substrates W1 to W9 in FIG. 5 to FIG. 22 correspond to the substrates W1 to W9 in FIG. 4. The substrate processing method described in FIG. 4 to FIG. 22 are performed under the control of the control device 4.

Hereinafter, a substrate transfer process performed by the second transfer device 31a is referred to as “PRA”. Further, liquid film forming processes performed in the liquid film forming device 32a on the negative X-axis side and the liquid film forming device 32a on the positive X-axis side included in the first unit block B1 are referred to as “SPIN1” and “SPIN2,” respectively. In addition, a supercritical drying process performed in the drying device 32b included in the first unit block B1 is referred to as “SCC1”. Further, liquid film forming processes performed in the liquid film forming device 32a on the negative X-axis side and the liquid film forming device 32a on the positive X-axis included in the second unit block B2 are referred to as “SPIN3” and “SPIN4”, respectively. Additionally, a supercritical drying process performed in the drying device 32b included in the second unit block B2 is referred to as “SCC2”.

First, as shown in FIG. 5, the second transfer device 31a takes out the substrate W1 from the transition device 23a, and transfers the taken out substrate W1 to the liquid film forming device 32a on the negative X-axis side in the first unit block B1. In the liquid film forming device 32a, the liquid film forming process (SPIN1) is performed on the substrate W1, as shown in FIG. 4. Specifically, the liquid film forming device 32a supplies the chemical liquid to the top surface of the substrate W1 that is held horizontally. The chemical liquid is supplied to the center of the top surface of the substrate W1 being rotated, and is diffused to the entire top surface of the substrates W1 in a radial direction by a centrifugal force to form a liquid film. Then, the liquid film forming device 32a supplies the rinse liquid to the top surface of the substrate W1 that is held horizontally. The rinse liquid is supplied to the center of the top surface of the substrate W1 being rotated, and is diffused to the entire top surface of the substrate W1 in the radial direction by the centrifugal force to form a liquid film. As a result, the liquid film of the chemical liquid is replaced with the liquid film of the rinse liquid. Next, the liquid film forming devices 32a supplies the drying liquid to the top surface of the substrate W1 that is held horizontally. The drying liquid is supplied to the center of the top surface of the substrate W1 being rotated, and is diffused to the entire top surface of the substrate W1 in the radial direction by the centrifugal force to form a liquid film. As a result, the liquid film of the rinse liquid is replaced with the liquid film of the drying liquid.

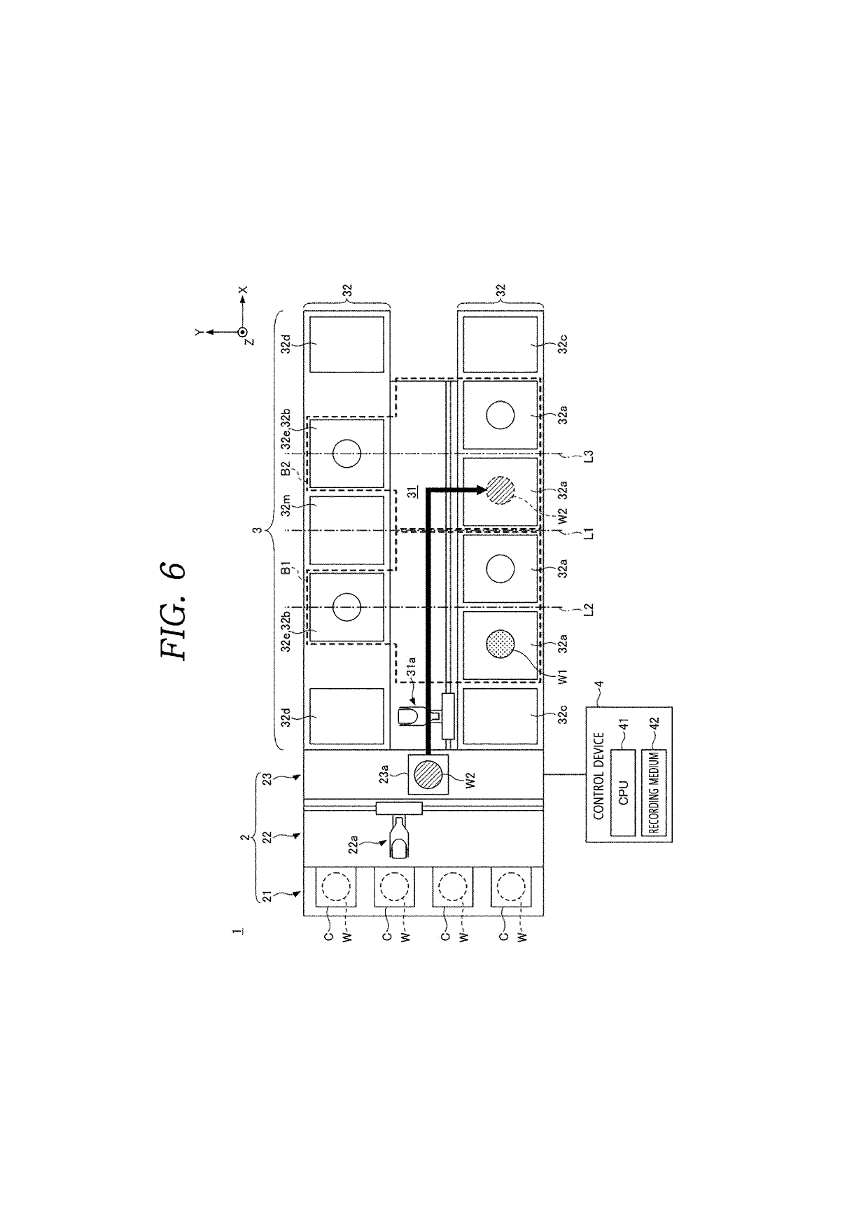

Subsequently, as shown in FIG. 6, the second transfer device 31a takes out the substrate W2 from the transition device 23a, and transfers the taken substrate W2 to the liquid film forming device 32a on the negative X-axis side in the second unit block B2. In the liquid film forming device 32a, the liquid film forming process (SPIN3) is performed on the substrate W2, as shown in FIG. 4. The liquid film forming process (SPIN3) may be the same process as the liquid film forming process (SPIN1).

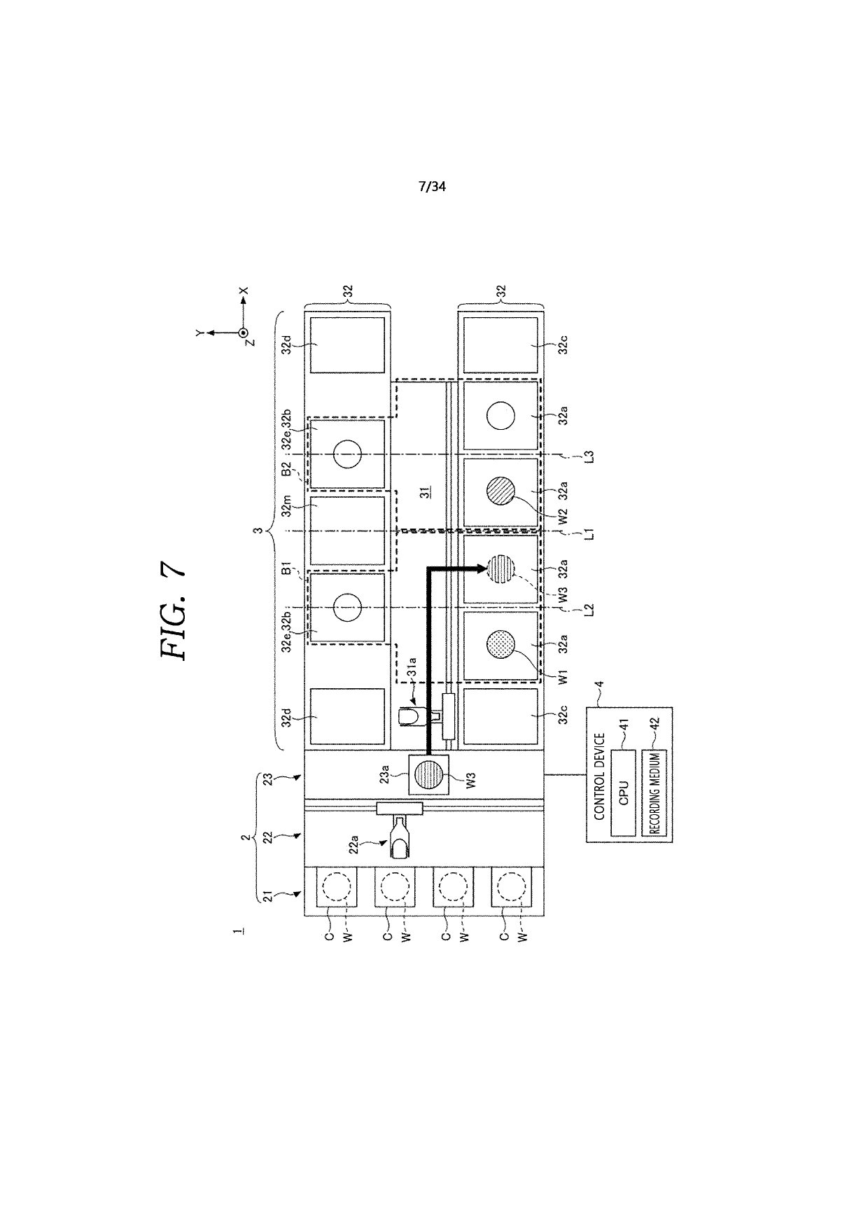

Next, as shown in FIG. 7, the second transfer device 31a takes out the substrate W3 from the transition device 23a, and transfers the taken substrate W3 to the liquid film forming device 32a on the positive X-axis side in the first unit block B1. In the liquid film forming device 32a, the liquid film forming process (SPIN2) is performed on the substrate W3, as shown in FIG. 4. The liquid film forming process (SPIN2) may be the same process as the liquid film forming process (SPIN1).

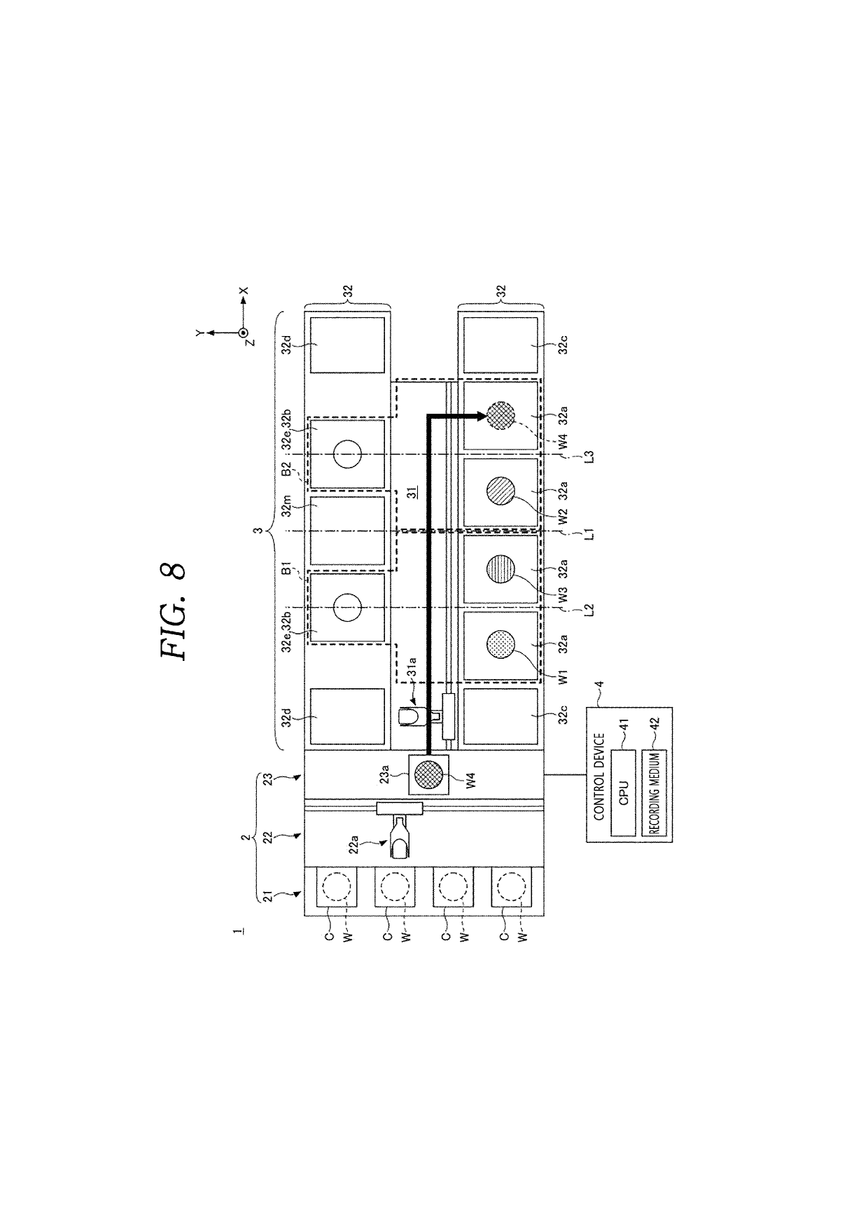

Thereafter, as shown in FIG. 8, the second transfer device 31a takes out the substrate W4 from the transition device 23a, and transfers the taken substrate W4 to the liquid film forming device 32a on the positive X-axis side in the second unit block B2. In the liquid film forming device 32a, the liquid film forming process (SPIN4) is performed on the substrate W4, as shown in FIG. 4. The liquid film forming process (SPIN4) may be the same process as the liquid film forming process (SPIN1).

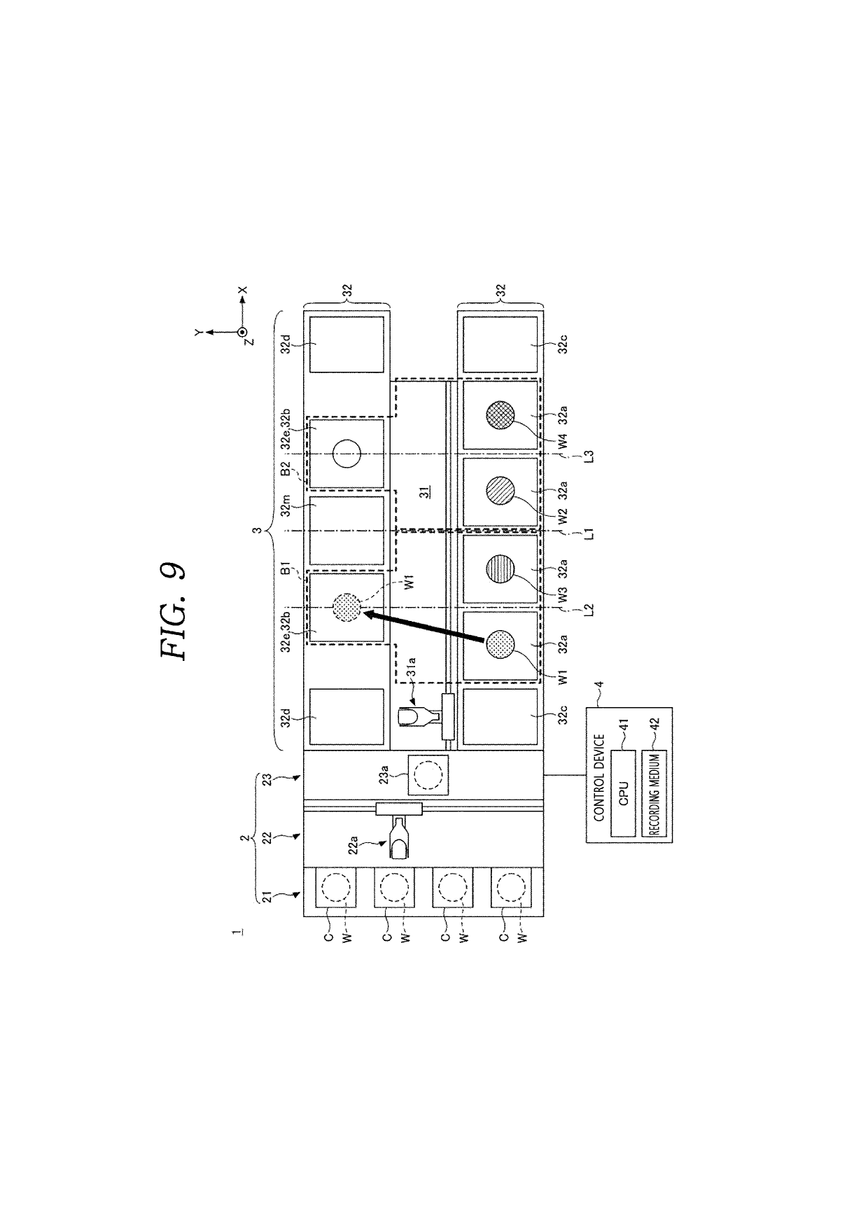

Then, as shown in FIG. 9, the second transfer device 31a takes out the substrate W1 from the liquid film forming device 32a on the negative X-axis side in the first unit block B1, and transfers the taken substrate W1 to the drying device 32b of the first unit block B1. In the drying device 32b, the supercritical drying process (SCC1) is performed on the substrate W1, as shown in FIG. 4. Specifically, the drying device 32b replaces the liquid film formed on the top surface of the substrate W1, which is held horizontally, with the supercritical fluid to thereby dry the substrate W1. By replacing the liquid film such as the drying liquid with the supercritical fluid, it is possible to suppress appearance of an interface between the liquid and the gas in the irregularity pattern of the substrate W1. As a result, generation of a surface tension can be suppressed, so that the collapse of the irregularity pattern can be suppressed.

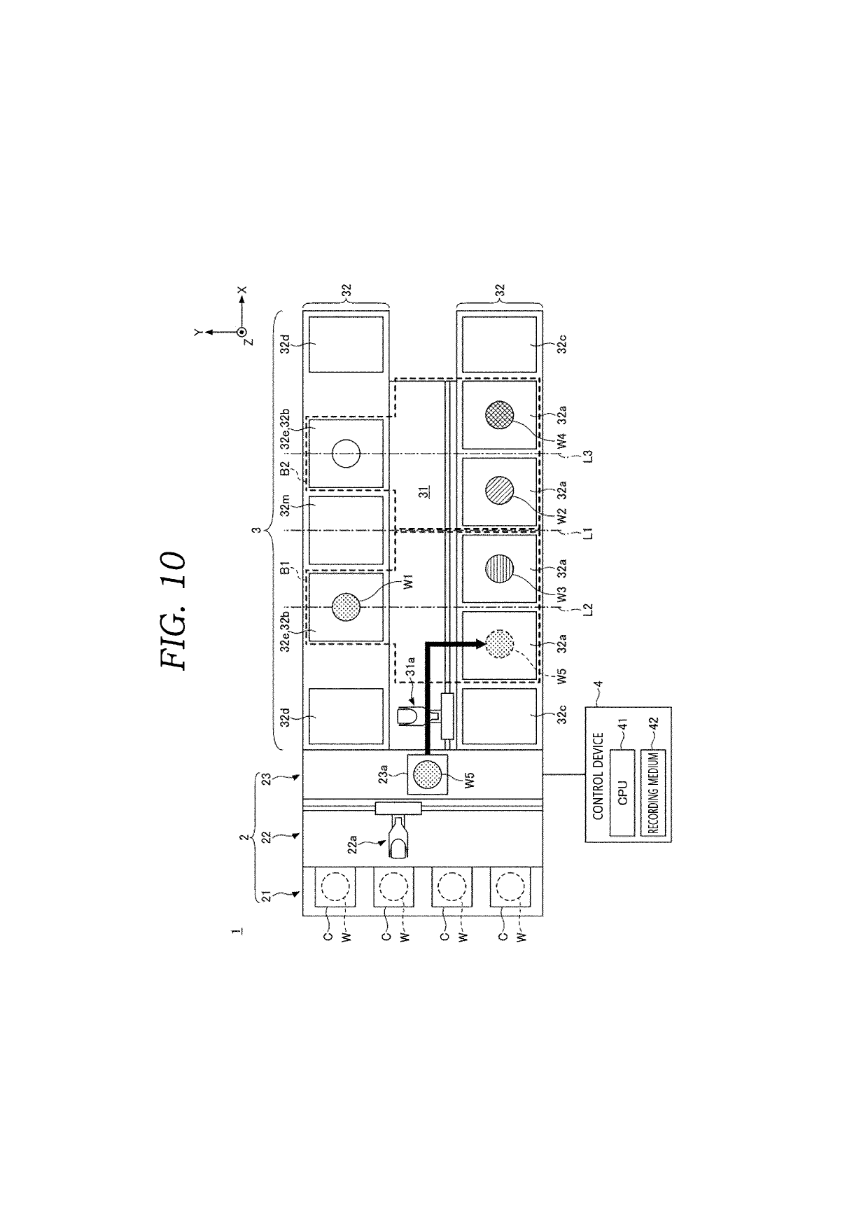

Subsequently, as shown in FIG. 10, the second transfer device 31a takes out the substrate W5 from the transition device 23a, and transfers the taken substrate W5 to the liquid film forming device 32a on the negative X-axis side in the first unit block B1. In the liquid film forming device 32a, the liquid film forming process (SPIN1) is performed on the substrate W5, as shown in FIG. 4.

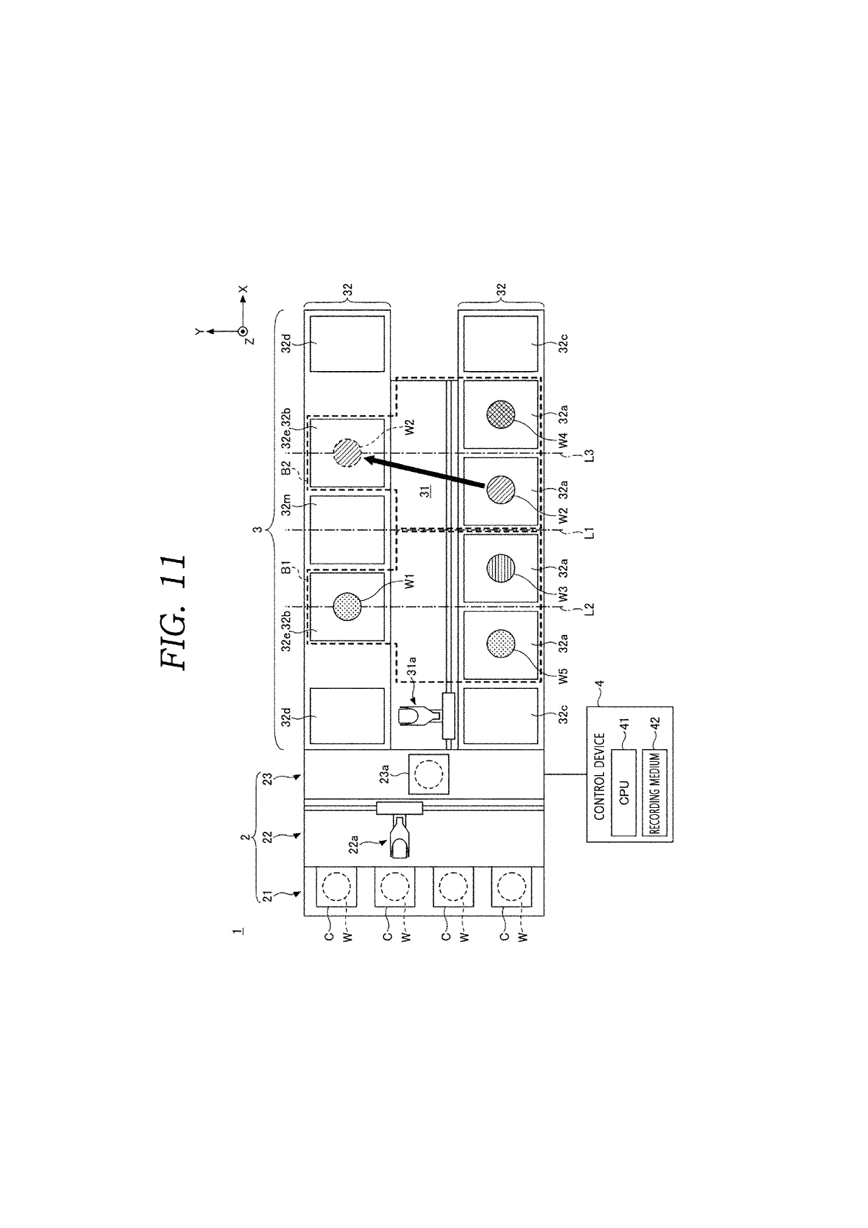

Next, as shown in FIG. 11, the second transfer device 31a takes out the substrate W2 from the liquid film forming device 32a on the negative X-axis in the second unit block B2, and transfers the taken substrate W2 to the drying device 32b of the second unit block B2. In the drying device 32b, the supercritical drying process (SCC2) is performed on the substrate W2, as shown in FIG. 4.

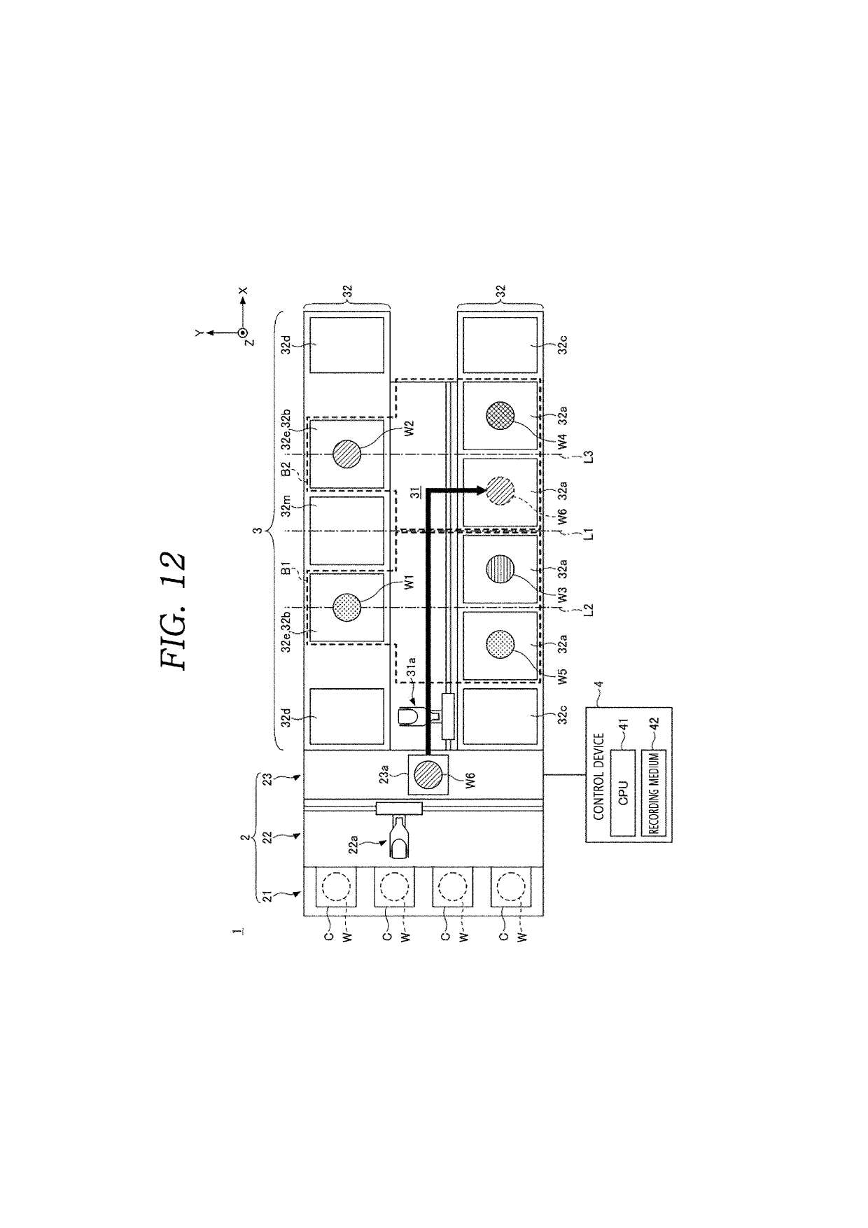

Then, as shown in FIG. 12, the second transfer device 31a takes out the substrate W6 from the transition device 23a, and transfers the taken substrate W6 to the liquid film forming device 32a on the negative X-axis side in the second unit block B2. In the liquid film forming device 32a, the liquid film forming process (SPIN3) is performed on the substrate W6, as shown in FIG. 4.

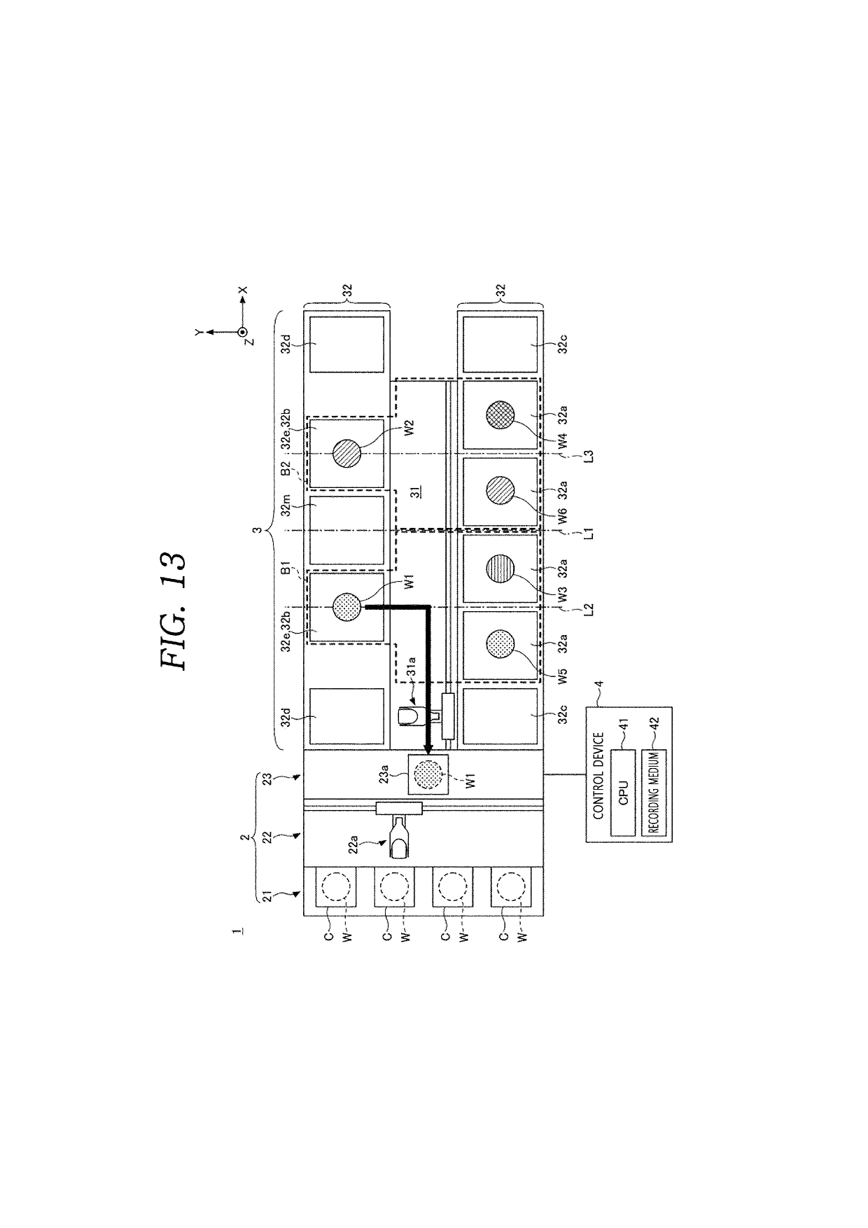

Thereafter, as shown in FIG. 13, the second transfer device 31a takes out the substrate W1 from the drying device 32b of the first unit block B1, and transfers the taken substrate W1 to the transition device 23a.

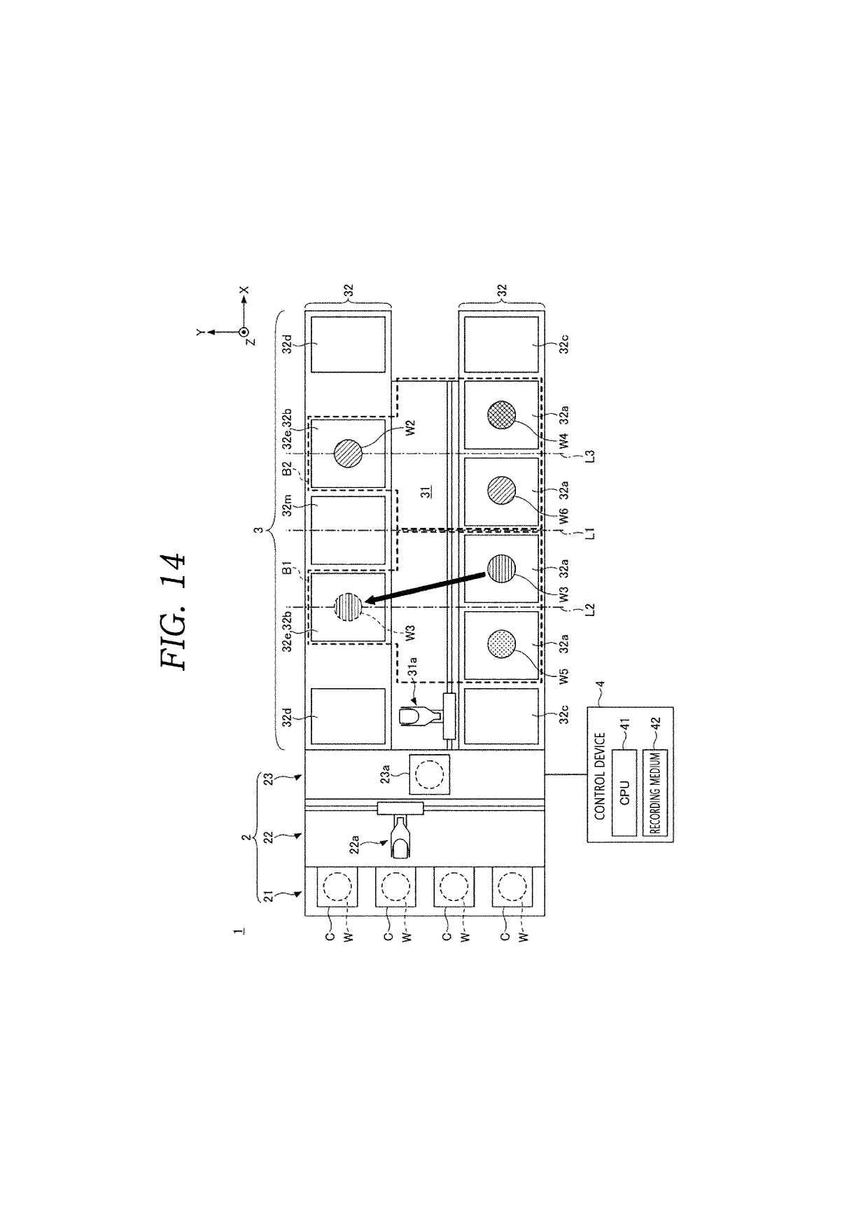

Afterwards, as shown in FIG. 14, the second transfer device 31a takes out the substrate W3 from the liquid film forming device 32a on the positive X-axis side in the first unit block B1, and transfers the taken substrate W3 to the drying device 32b of the first unit block B1. In the drying device 32b, the supercritical drying process (SCC1) is performed on the substrate W3, as shown in FIG. 4. Here, the two liquid film forming devices 32a of the first unit block B1 are arranged axisymmetrically about the virtual line L2, and the drying device 32b of the first unit block B1 has its center on the virtual line L2. In this case, the length of the transfer path of the substrate W1 between the liquid film forming device 32a on the negative X-axis side and the drying device 32b, and the length of transfer path of the substrate W3 between the liquid film forming device 32a on the positive X-axis side and the drying device 32b become equal. Accordingly, the times taken until the liquid film formed on the top surface of the substrate W1 in the liquid film forming device 32a on the negative X-axis side and the liquid film formed on the top surface of the substrate W3 in the liquid film forming device 32a on the positive X-axis side are replaced with the supercritical fluid in the drying device 32b can be made equal. As a result, the non-uniformity in processing quality between the substrate W1 processed by the liquid film forming device 32a on the negative X-axis side and the substrate W3 processed by the liquid film forming device 32a on the positive X-axis side can be reduced. As depicted in FIG. 4, an end time of the liquid film formation process (SPIN2) performed on the substrate W3 may be adjusted to be the same as an end time of the supercritical drying process (SCC1) performed on the substrate W1. In this case, after the liquid film forming process (SPIN2) is completed, the substrate W3 can be transferred to the drying device 32b without standing by in the liquid film forming device 32a. Accordingly, the liquid film of the drying liquid formed on the top surface of the substrate W3 by the liquid film forming process (SPIN2) can be suppressed from being dried. Therefore, the collapse of the irregularity pattern of the substrate W3 can be suppressed. Alternatively, the end time of the liquid film formation process (SPIN2) performed on the substrate W3 may be adjusted to be later than the end time of the supercritical drying process (SCC1) performed on the substrate W1. In this case as well, the substrate W3 can be transferred to the drying device 32b without standing by in the liquid film forming device 32a.

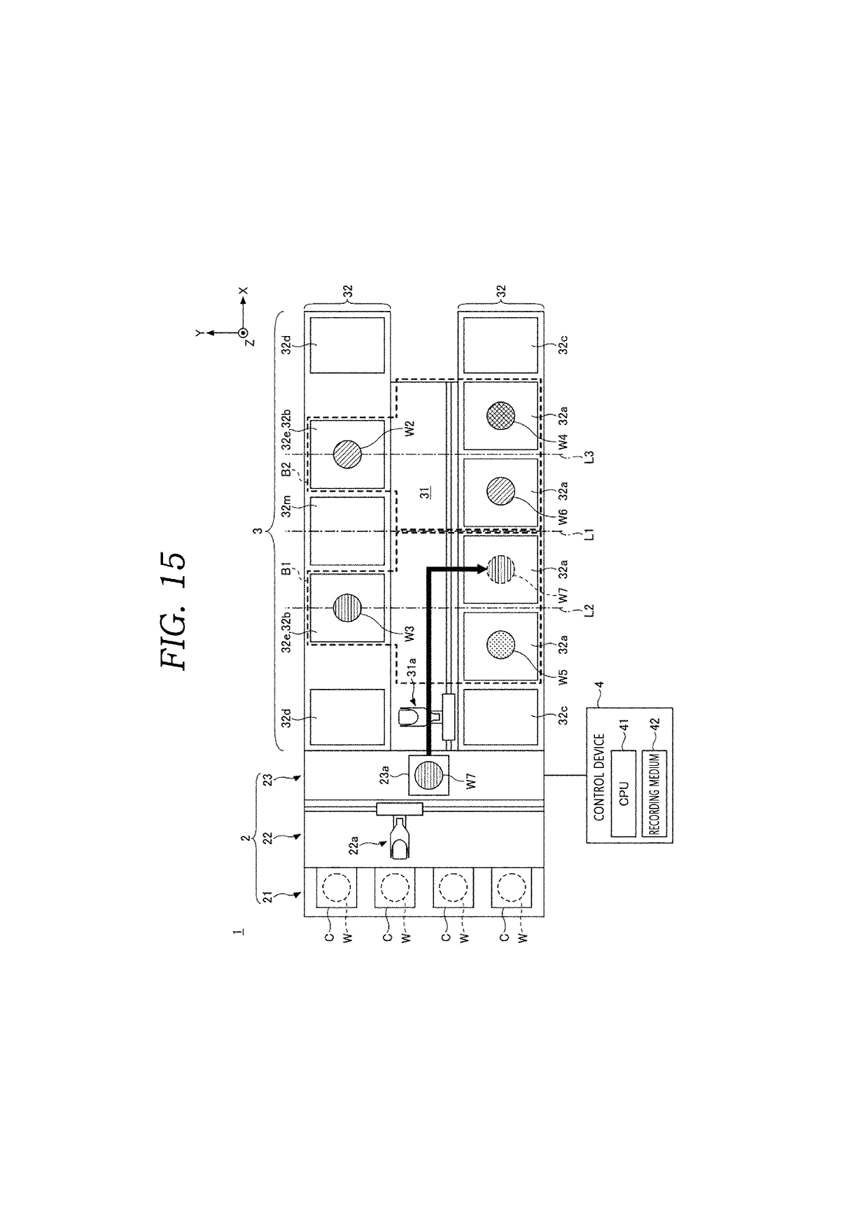

Next, as shown in FIG. 15, the second transfer device 31a takes out the substrate W7 from the transition device 23a, and transfers the taken substrate W7 to the liquid film forming device 32a on the positive X-axis side in the first unit block B1. In the liquid film forming device 32a, the liquid film forming process SPIN2 is performed on the substrate W7, as shown in FIG. 4.

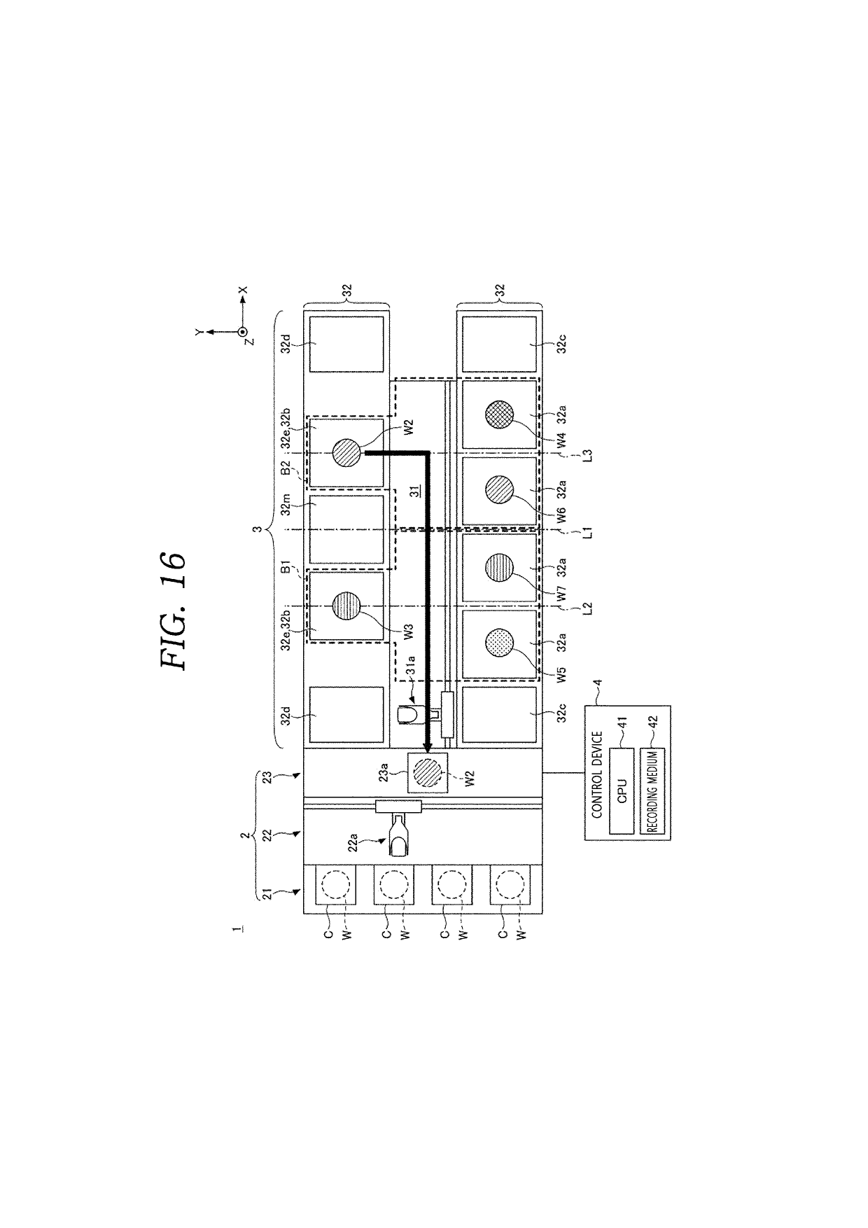

Then, as shown in FIG. 16, the second transfer device 31a takes out the substrate W2 from the drying device 32b of the second unit block B2, and transfers the taken substrate W2 to the transition device 23a.

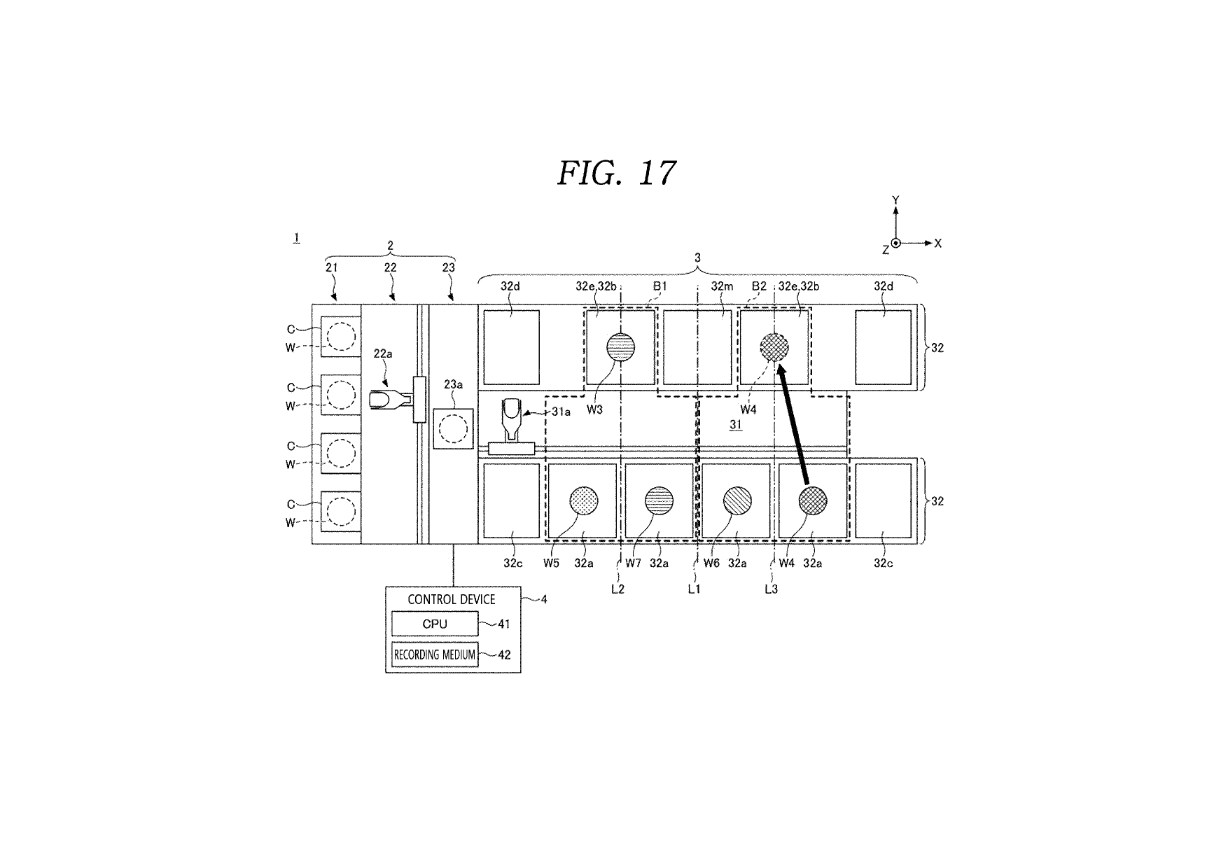

Subsequently, as shown in FIG. 17, the second transfer device 31a takes out the substrate W4 from the liquid film forming device 32a on the positive X-axis side in the second unit block B2, and transfers the taken substrate W4 to the drying device 32b of the second unit block B2. In the drying device 32b, the supercritical drying process (SCC2) is performed on the substrate W4, as shown in FIG. 4. Here, the two liquid film forming devices 32a of the second unit block B2 are arranged axisymmetrically about a virtual line L3, and the drying device 32b of the second unit block B2 has its center on the virtual line L3. In this case, the length of the transfer path of the substrate W2 between the liquid film forming device 32a on the negative X-axis side and the drying device 32b, and the length of the transfer path of the substrate W4 between the liquid film forming device 32a on the positive X-axis side and the drying device 32b become equal. Accordingly, the times taken until the liquid film formed on the top surface of the substrate W2 by the liquid film forming device 32a on the negative X-axis side and the liquid film formed on the top surface of the substrate W4 by the liquid film forming device 32a on the positive X-axis side are replaced with the supercritical fluid in the drying device 32b can be made equal. As a result, the non-uniformity in processing quality between the substrate W2 processed by the liquid film forming device 32a on the negative X-axis side and the substrate W4 processed by the liquid film forming device 32a on the positive X-axis side can be reduced. As illustrated in FIG. 4, an end time of the liquid film forming process (SPIN4) performed on the substrate W4 may be adjusted to be the same as an end time of the supercritical drying process (SCC2) performed on the substrate W2. In this case, after the liquid film forming process (SPIN4) is completed, the substrate W4 can be transferred to the drying device 32b without standing by in the liquid film forming device 32a. Thereby, drying of the liquid film of the drying liquid formed on the top surface of the substrate W4 by the liquid film forming process (SPIN4) can be suppressed. For this reason, the collapse of the irregularity pattern of the substrate W4 can be suppressed. Alternatively, the end time of the liquid film forming process (SPIN4) performed on the substrate W4 may be adjusted to be later than the end time of the supercritical drying process (SCC2) performed on the substrate W2. In this case as well, the substrate W4 can be transferred to the drying device 32b without standing by in the liquid film forming device 32a.

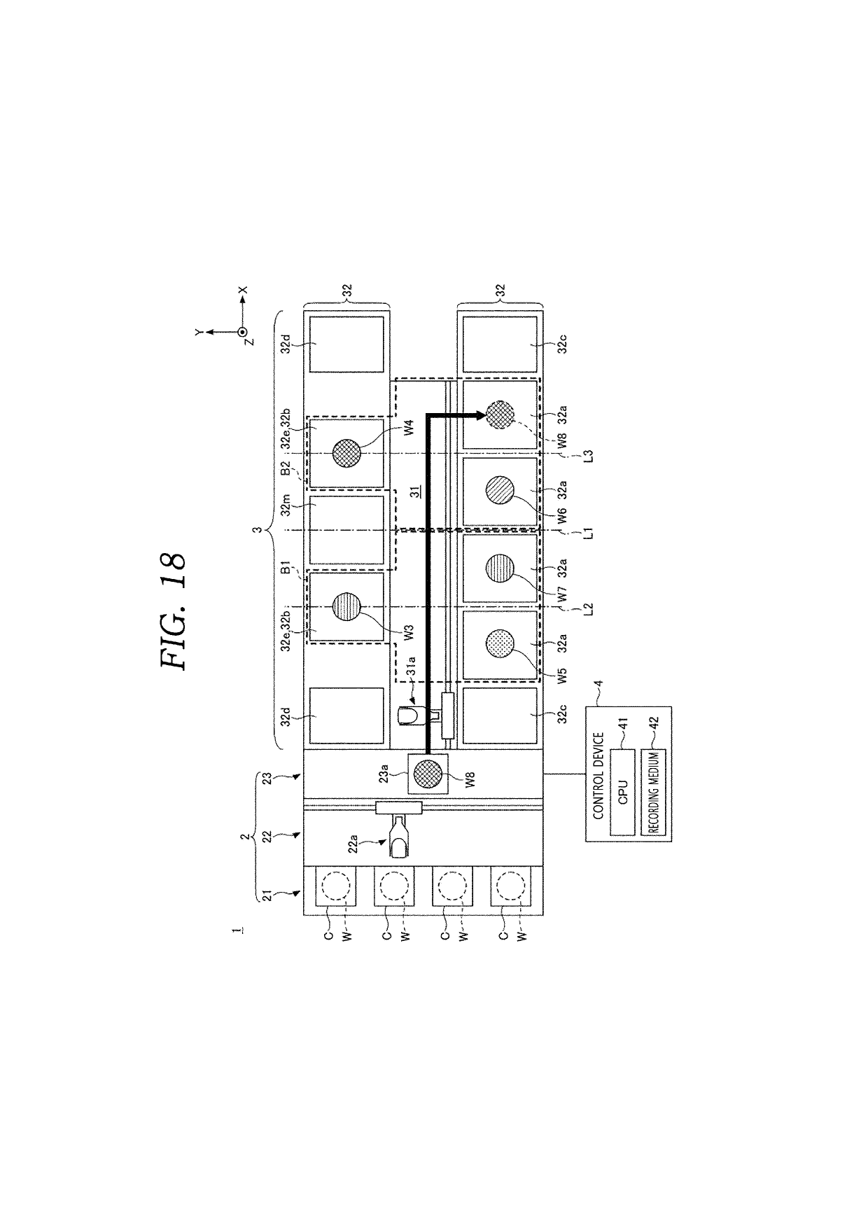

Thereafter, as shown in FIG. 18, the second transfer device 31a takes out the substrate W8 from the transition device 23a, and transfers the taken substrate W8 to the liquid film forming device 32a on the positive X-axis side in the second unit block B2. In the liquid film forming device 32a, the liquid film forming process (SPIN4) is performed on the substrate W8, as shown in FIG. 4.

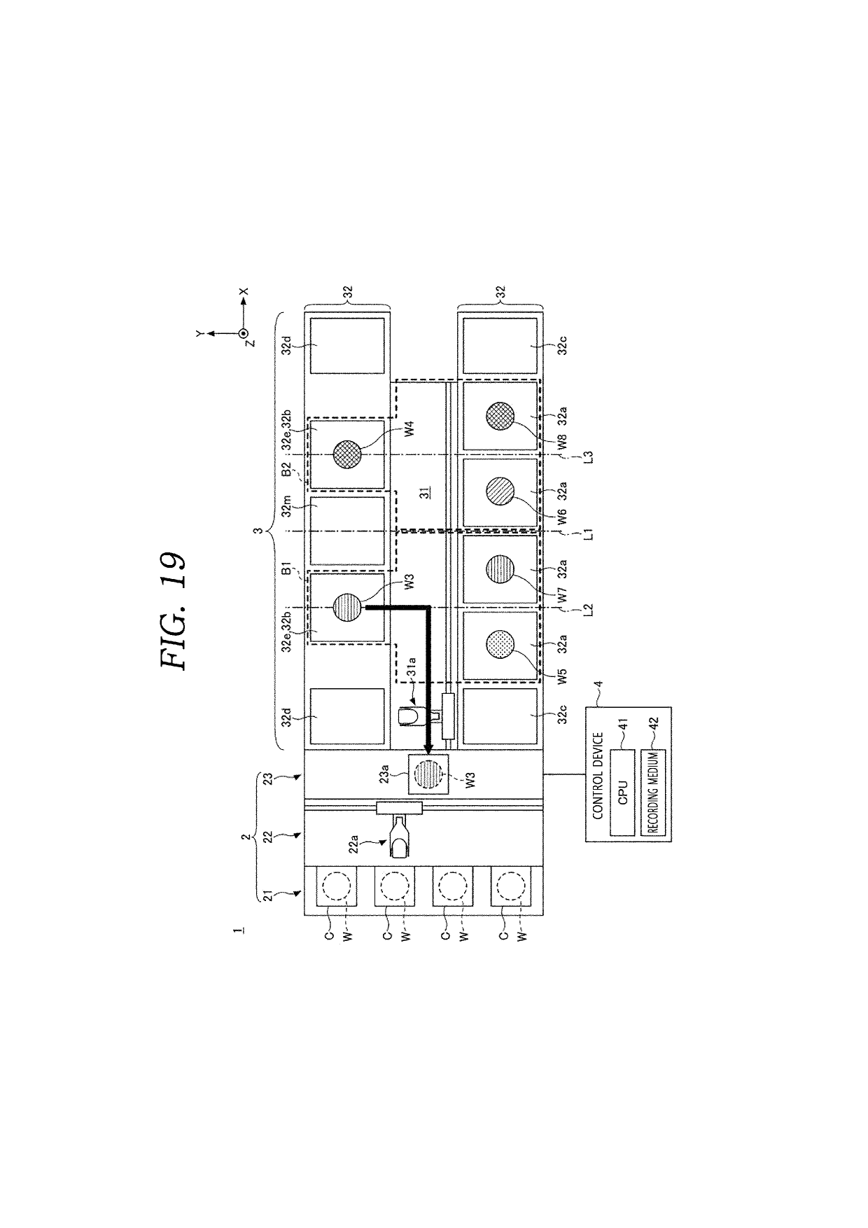

Then, as depicted in FIG. 19, the second transfer device 31a takes out the substrate W3 from the drying device 32b of the first unit block B1, and transfers the taken substrate W3 to the transition device 23a.

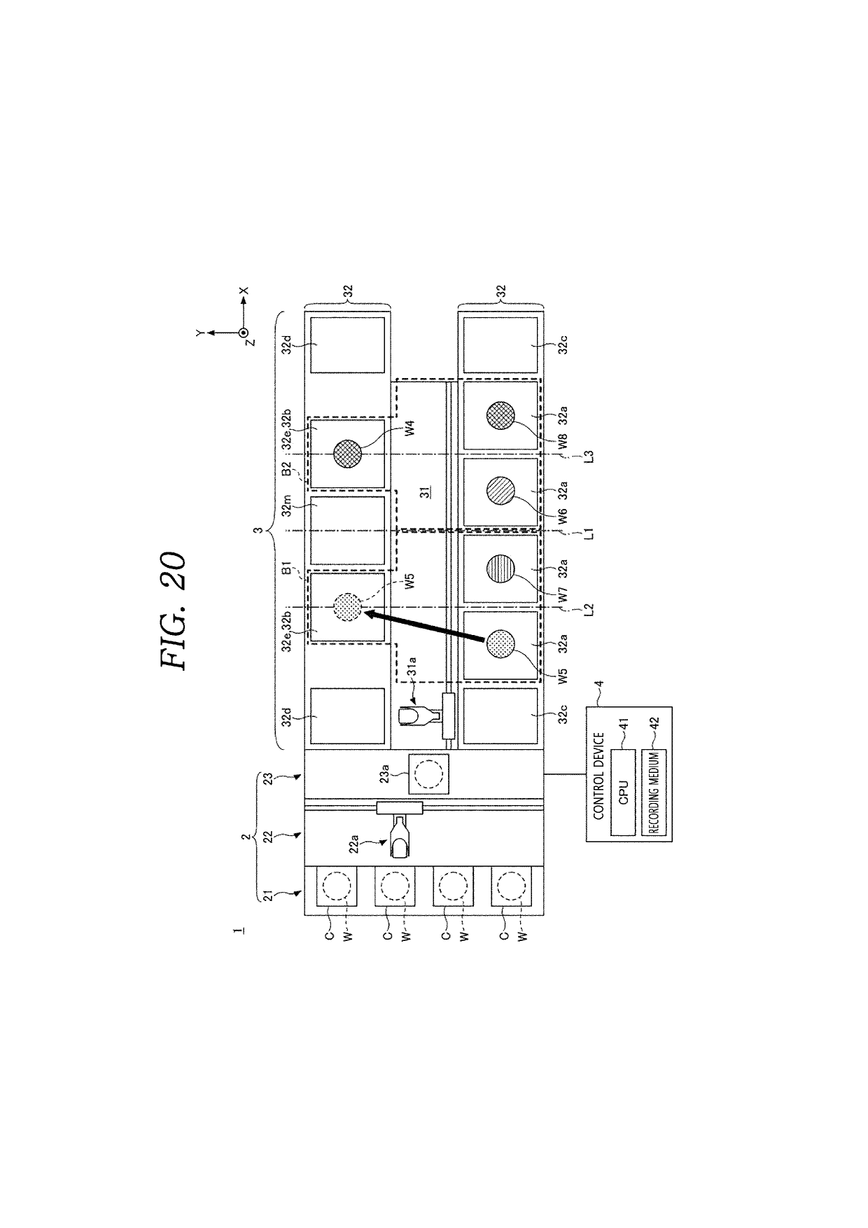

Next, as shown in FIG. 20, the second transfer device 31a takes out the substrate W5 from the liquid film forming device 32a on the negative X-axis side in the first unit block B1, and transfers the taken substrate W5 to the drying device 32b of the first unit block B1. In the drying device 32b, the supercritical drying process (SCC1) is performed on the substrate W5, as shown in FIG. 4. As depicted in FIG. 4, an end time of the liquid film formation process (SPIN1) performed on the substrate W5 may be adjusted to be the same as an end time of the supercritical drying process (SCC1) performed on the substrate W3. In this case, after the liquid film forming process (SPIN1) is completed, the substrate W5 can be transferred to the drying device 32b without standing by in the liquid film forming device 32a. Accordingly, the liquid film of the drying liquid formed on the top surface of the substrate W5 by the liquid film forming process (SPIN1) can be suppressed from being dried. Thus, the collapse of the irregularity pattern of the substrate W5 can be suppressed. Alternatively, the end time of the liquid film formation process (SPIN1) performed on the substrate W5 may be adjusted to be later than the end time of the supercritical drying process (SCC1) performed on the substrate W3. In this case as well, the substrate W5 can be transferred to the drying device 32b without standing by in the liquid film forming device 32a.

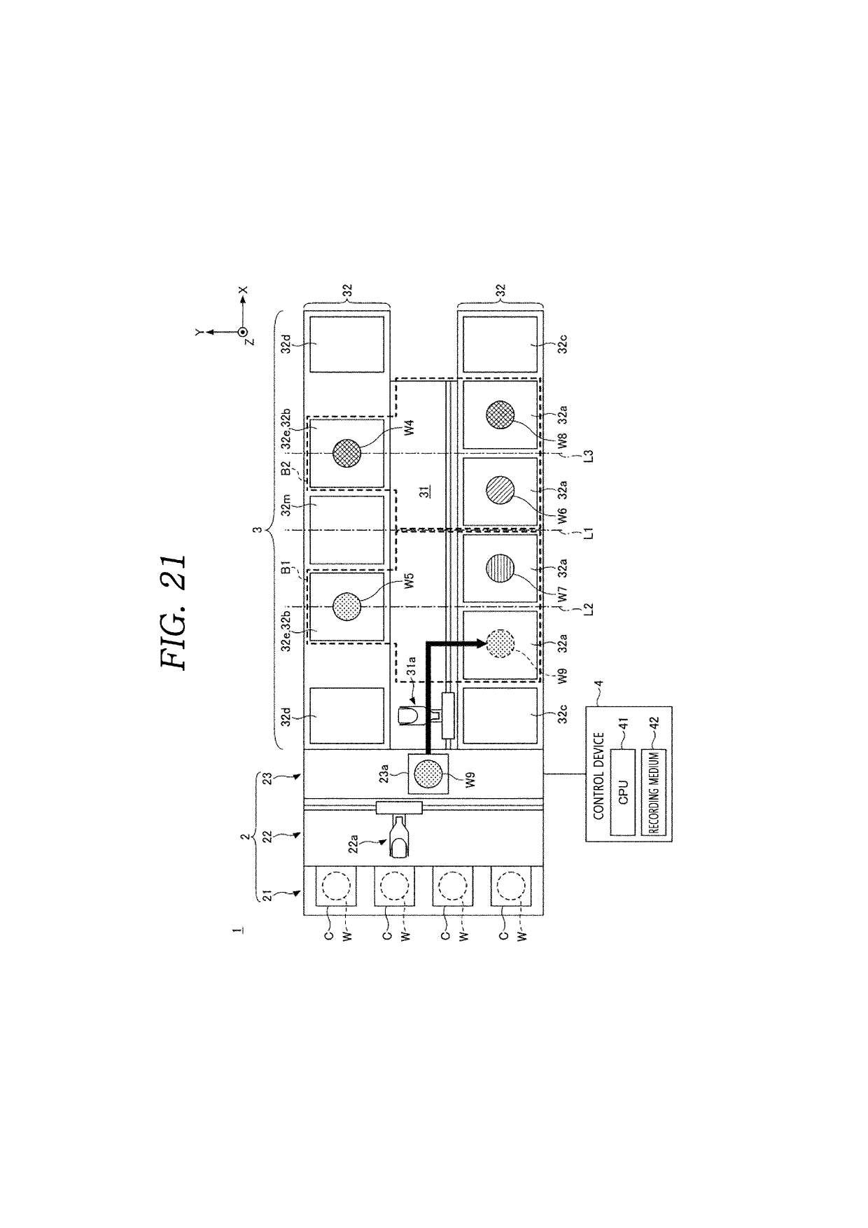

Thereafter, as shown in FIG. 21, the second transfer device 31a takes out the substrate W9 from the transition device 23a, and transfers the taken substrate W9 to the liquid film forming device 32a on the negative X-axis side in the first unit block B1. In the liquid film forming device 32a, the liquid film forming process (SPIN1) is performed on the substrate W9, as shown in FIG. 4.

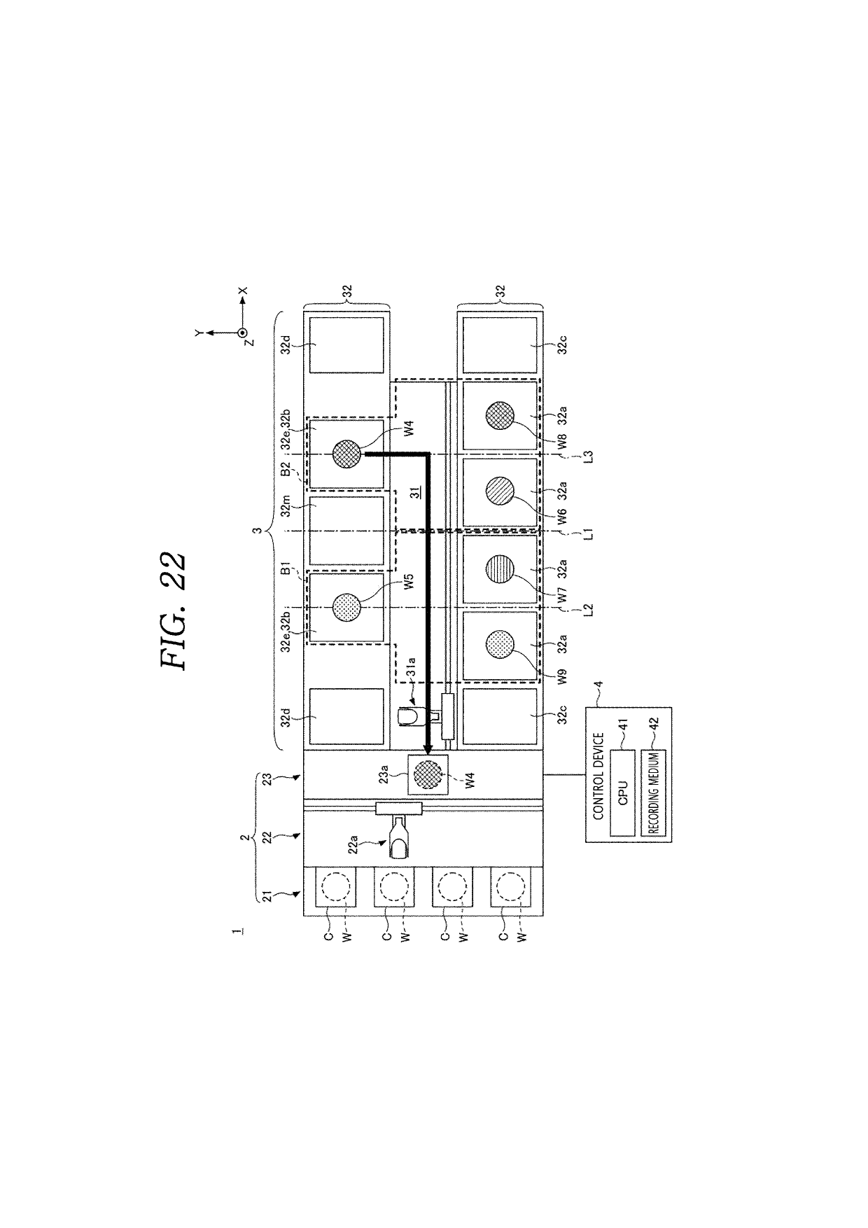

Then, as shown in FIG. 22, the second transfer device 31a takes out the substrate W4 from the drying device 32b of the second unit block B2, and transfers the taken substrate W4 to the transition device 23a.

Afterwards, by repeating the operations shown in FIG. 11 to FIG. 22, the multiple substrates W can be processed continually.

### Intermediate area

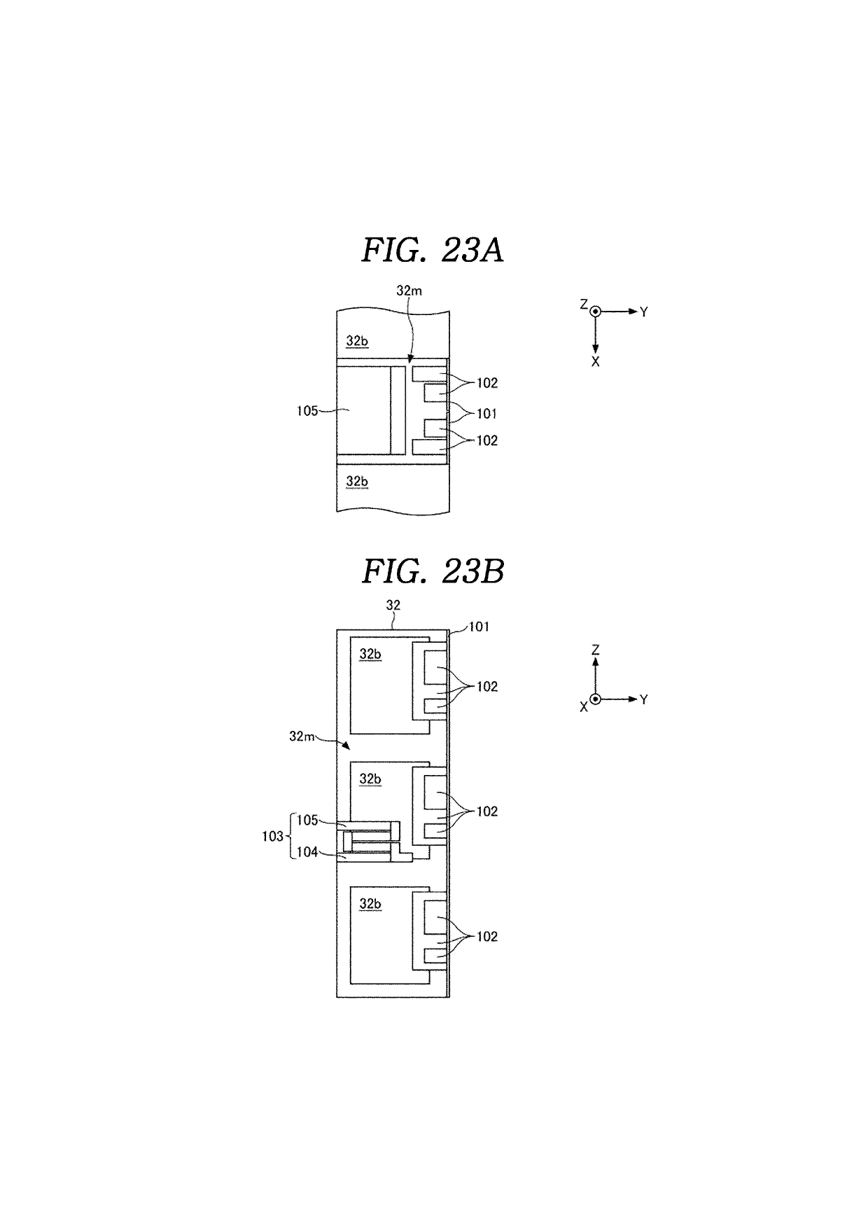

Referring to FIG. 23A and FIG. 23B, a state of the intermediate area 32m when the substrate processing apparatus 1 is in operation will be described. FIG. 23A and FIG. 23B are diagrams illustrating the intermediate area 32b when the device is in operation. FIG. 23A and FIG. 23B are a plan view and a side view, respectively, showing a part of the processing block 32 including the intermediate area 32m.

As shown in FIG. 23A and FIG. 23B, when the device is in operation, a door 101 is closed, so the intermediate area 32m is isolated from an external space. The door 101 may be, for example, of a left-right swing type. An electronic control device group that controls the operation of the drying device 32b may be provided to an inner surface of the door 101. In the intermediate area 32m, a workbench 103 is provided. The workbench 103 includes a step stool 104 and a ladder 105. The step stool 104 is fixed at a height position approximately on a level with the drying device 32b of an intermediate level. The ladder 105 is fixed to the step stool 104. The ladder 105 is configured to be foldable. When the device is in operation, the ladder 105 is folded and placed on the step stool 104.

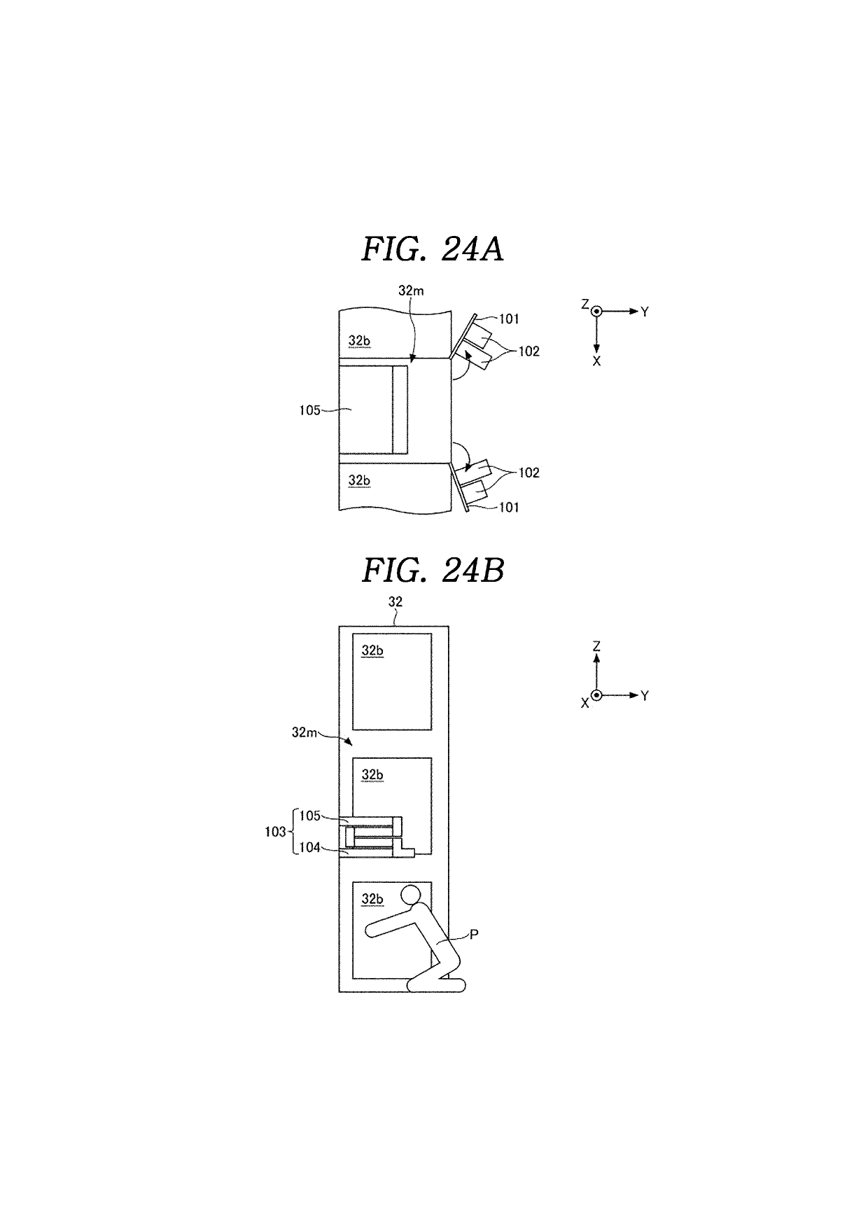

With reference to FIG. 24A and FIG. 24B, a method of performing the maintenance of the drying device 32b of the lower level will be described. FIG. 24A and FIG. 24B are diagrams showing the intermediate area 32m during the maintenance of the lower level. FIG. 24A and FIG. 24B are a plan view and a side view, respectively, showing a part of the processing block 32 including the intermediate area 32m.

As shown in FIG. 24A and FIG. 24B, during the maintenance of the lower level, a worker P opens the door 101 to allow the intermediate area 32m to communicate with the external space. Thus, the worker P can enter the intermediate area 32m. In the intermediate area 32m, the worker P can perform the maintenance of the drying device 32b of the lower level without using the workbench 103.

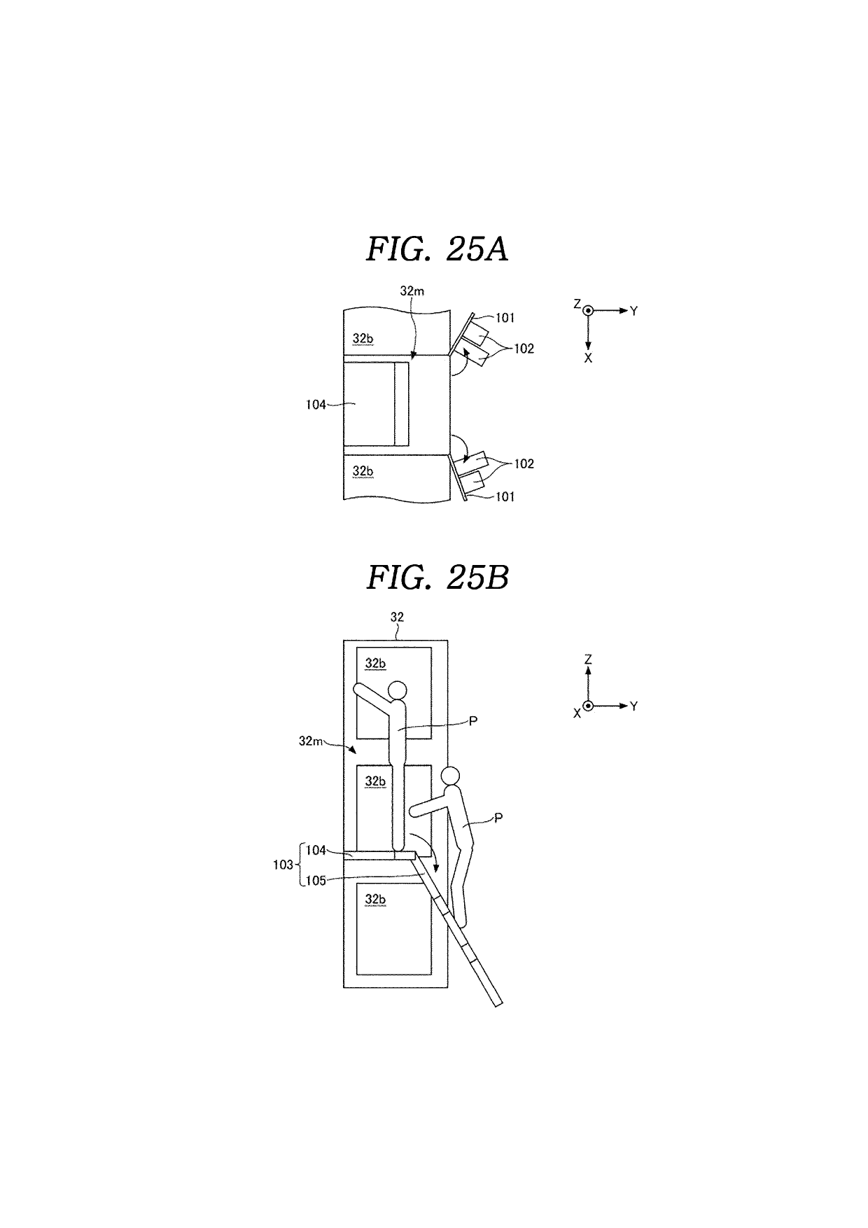

Referring to FIG. 25A and FIG. 25B, a method of performing the maintenance of the drying devices 32b of the intermediate level and the upper level will be described. FIG. 25A and FIG. 25B are diagrams showing the intermediate area 32m during the maintenance of the intermediate and upper levels. FIG. 25B and FIG. 25B are a plan view and a side view, respectively, showing a part of the processing block 32 including the intermediate area 32m.

As shown in FIG. 25A and FIG. 25B, during the maintenance of the intermediate and upper levels, the worker P first opens the door 101 to allow the intermediate area 32m to communicate with the external space. Then, the worker P unfolds the folded ladder 105. On the ladder 105 or the step stool 104, the worker P can perform the maintenance of the drying devices 32b of the intermediate and upper levels.

### Modification examples of substrate processing apparatus

### First modification example

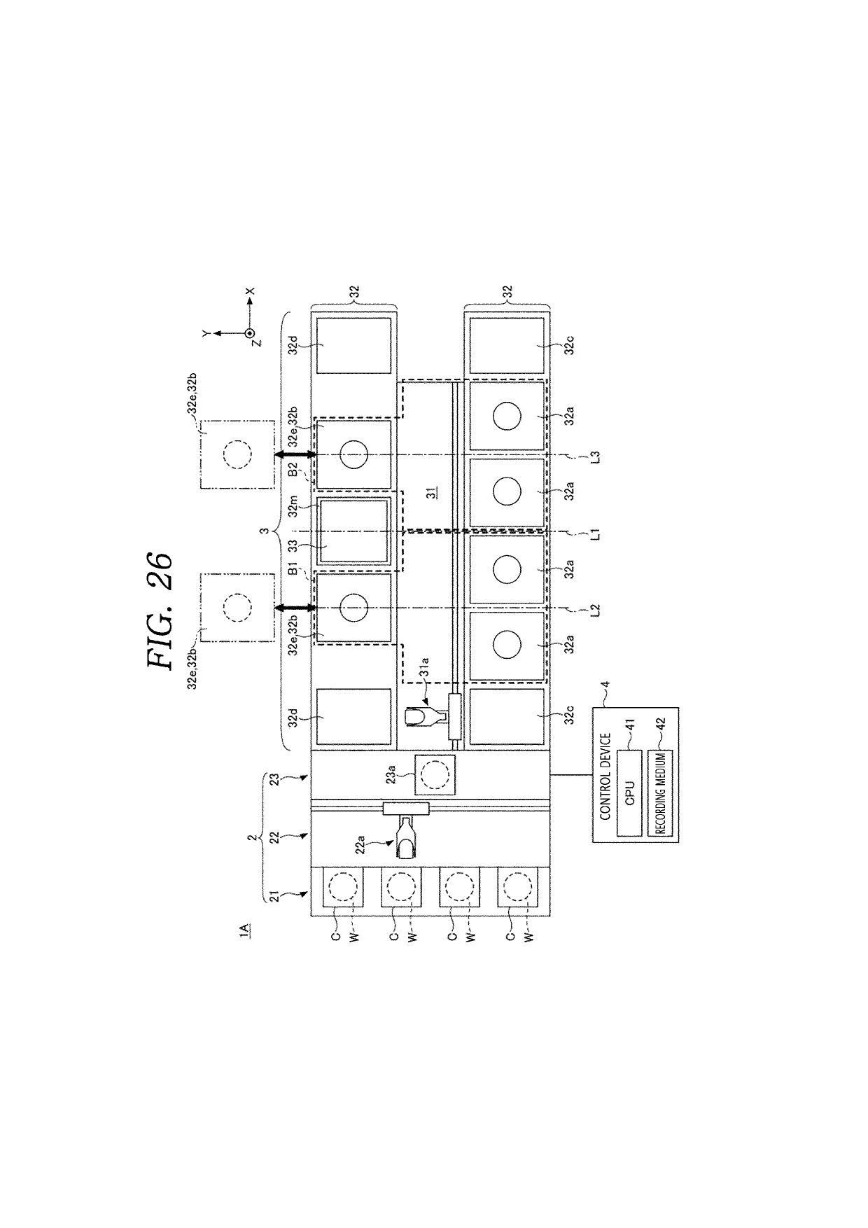

Referring to FIG. 26, a substrate processing apparatus 1A according to a first modification example of the exemplary embodiment will be described. FIG. 26 is a plan view of the substrate processing apparatus 1A according to the first modification example of the exemplary embodiment.

In the first modification example, as illustrated in FIG. 26, two drying devices 32b are provided on one side (positive Y-axis side) of the transfer block 31, and the intermediate area 32m is provided between the two drying devices 32b. The intermediate area 32m is not an area where a worker enters during the maintenance, and the electrical equipment block 33 can be provided in the entire intermediate area 32m. In this case, the overall height of the substrate processing apparatus 1A can be reduced. In the first modification example, the drying device 32b and the inspecting device 32e are configured to be movable in a direction (positive Y-axis direction) away from the transfer block 31. In this case, the worker P can repair or replace members near carry-in/out openings for the substrate W in the drying device 32b and the inspecting device 32e without needing to enter the intermediate area 32m. In addition, the drying device 32b and the inspecting device 32e are also movable in a direction (negative Y-axis direction) approaching the transfer block 31 as well.

Moreover, in the first modification example, only the drying device 32b may be configured to be movable in the positive and negative Y-axis directions.

### Second modification example

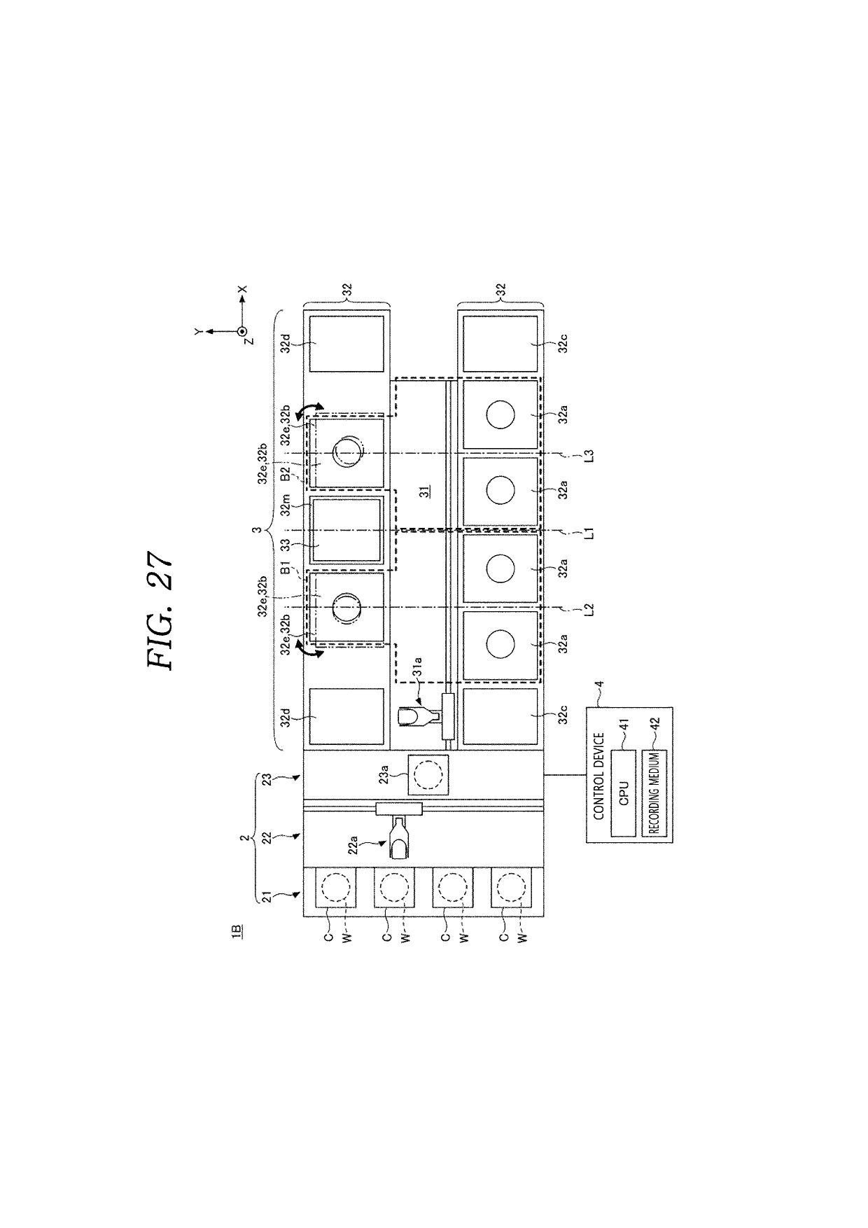

Referring to FIG. 27, a substrate processing apparatus 1B according to a second modification example of the exemplary embodiment will be described. FIG. 27 is a plan view of the substrate processing apparatus 1B according to the second modification example of the exemplary embodiment.

In the second modification example, as depicted in FIG. 27, two drying devices 32b are disposed on one side (positive Y-axis side) of the transfer block 31, and the intermediate area 32m is provided between the two drying devices 32b. The intermediate area 32m is not an area where a worker enters during the maintenance, and the electrical equipment block 33 can be provided in the entire intermediate area 32m. In this case, the overall height of the substrate processing apparatus 1B can be reduced. In the second modification example, the drying devices 32b and the inspecting devices 32e are configured to be rotatable horizontally. For example, the drying device 32b and the inspecting device 32e of the first unit block B1 may be configured to be rotated 90 degrees counterclockwise. For example, the drying device 32b and the inspecting device 32e of the second unit block B2 may be configured to be rotated 90 degrees clockwise. In this case, surfaces of the drying device 32b and the inspecting device 32e facing the intermediate area 32m is directed toward the positive Y-axis side. Thus, the worker P can repair or replace members near the carry-in/out openings for the substrate W in the drying device 32b and the inspecting device 32e without needing to enter the intermediate area 32m. Further, the drying device 32b and the inspecting device 32e may be configured to be rotated 90 degrees both clockwise and counterclockwise.

Alternatively, in the second modification example, only the drying device 32b may be configured to be rotatable horizontally.

### Third modification example

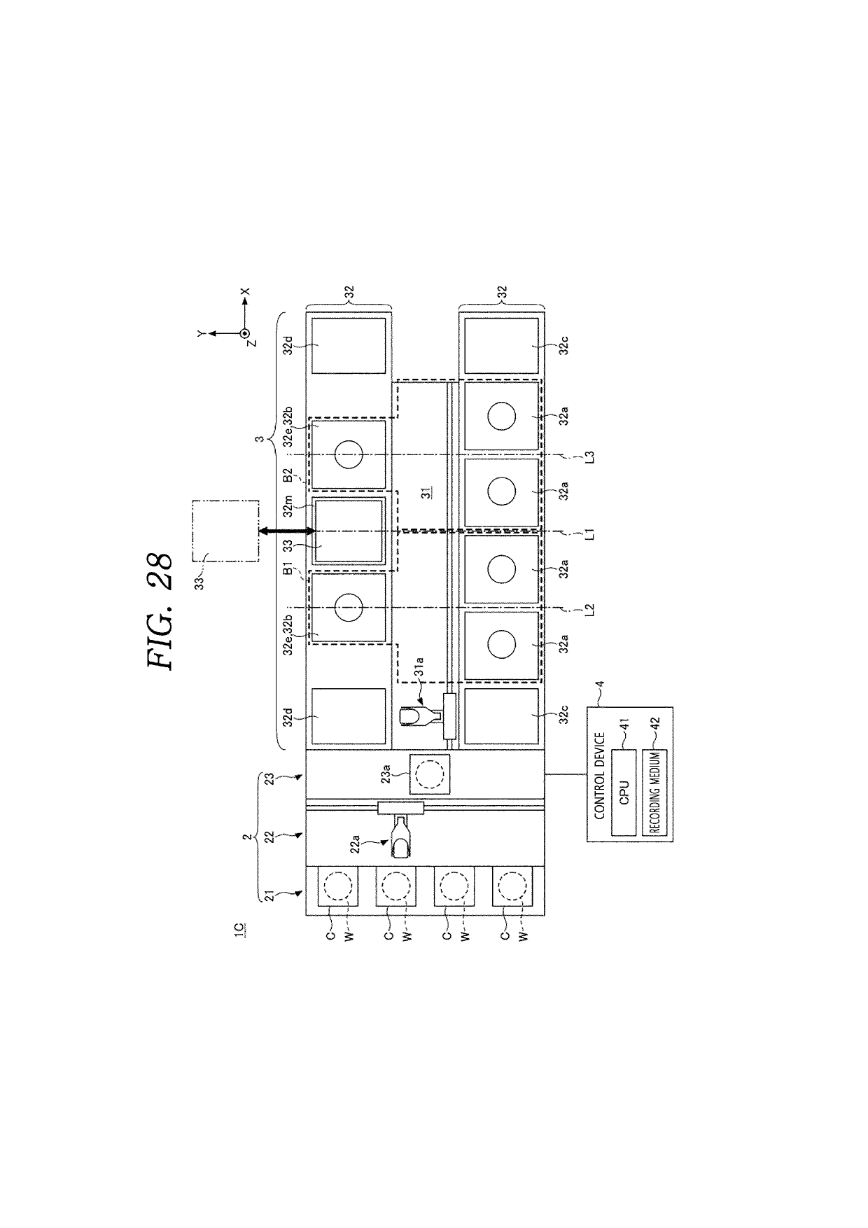

Referring to FIG. 28, a substrate processing apparatus 1C according to a third modification example of the exemplary embodiment will be described. FIG. 28 is a plan view of the substrate processing apparatus 1C according to the third modification example of the exemplary embodiment.

In the third modification example, the electrical equipment block 33 is provided in the intermediate area 32m, as illustrated in FIG. 28. In this case, the overall height of the substrate processing apparatus 1C can be reduced. In the third modification example, the electrical equipment block 33 is configured to be movable in a direction (positive Y-axis direction) away from the transfer block 31. In this case, when performing the maintenance of the drying device 32b, the worker P moves the electrical equipment block 33 in the positive Y-axis direction to the outside of the intermediate area 32m. Thus, the worker P can enter the intermediate area 32m and perform the maintenance of the drying device 32b. Further, the worker P does not have to completely move the electrical equipment block 33 to the outside of the intermediate area 32m. The position to which the electrical equipment block 33 is moved can be any position where the worker P can enter the intermediate area 32m, and it may be a position where a part of the electrical equipment block 33 may be left in the intermediate area 32m.

### Fourth modification example

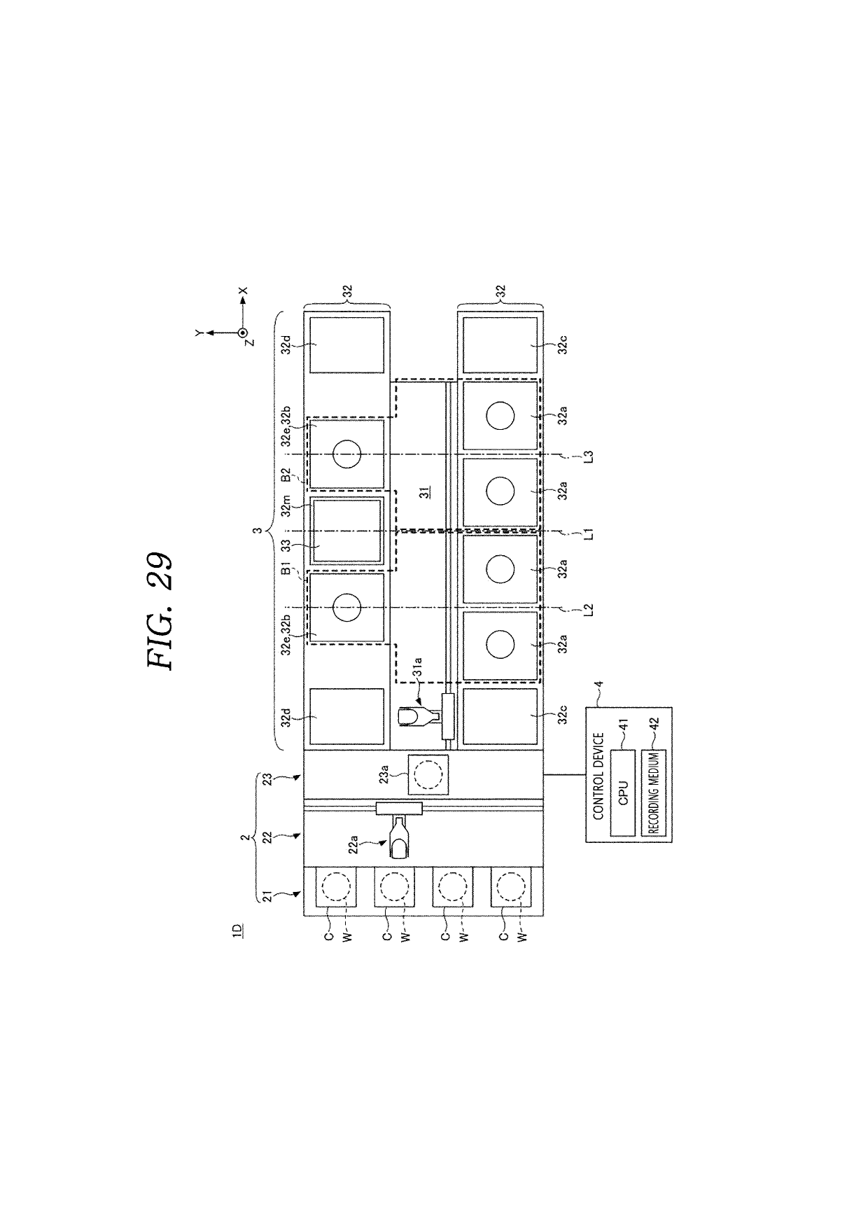

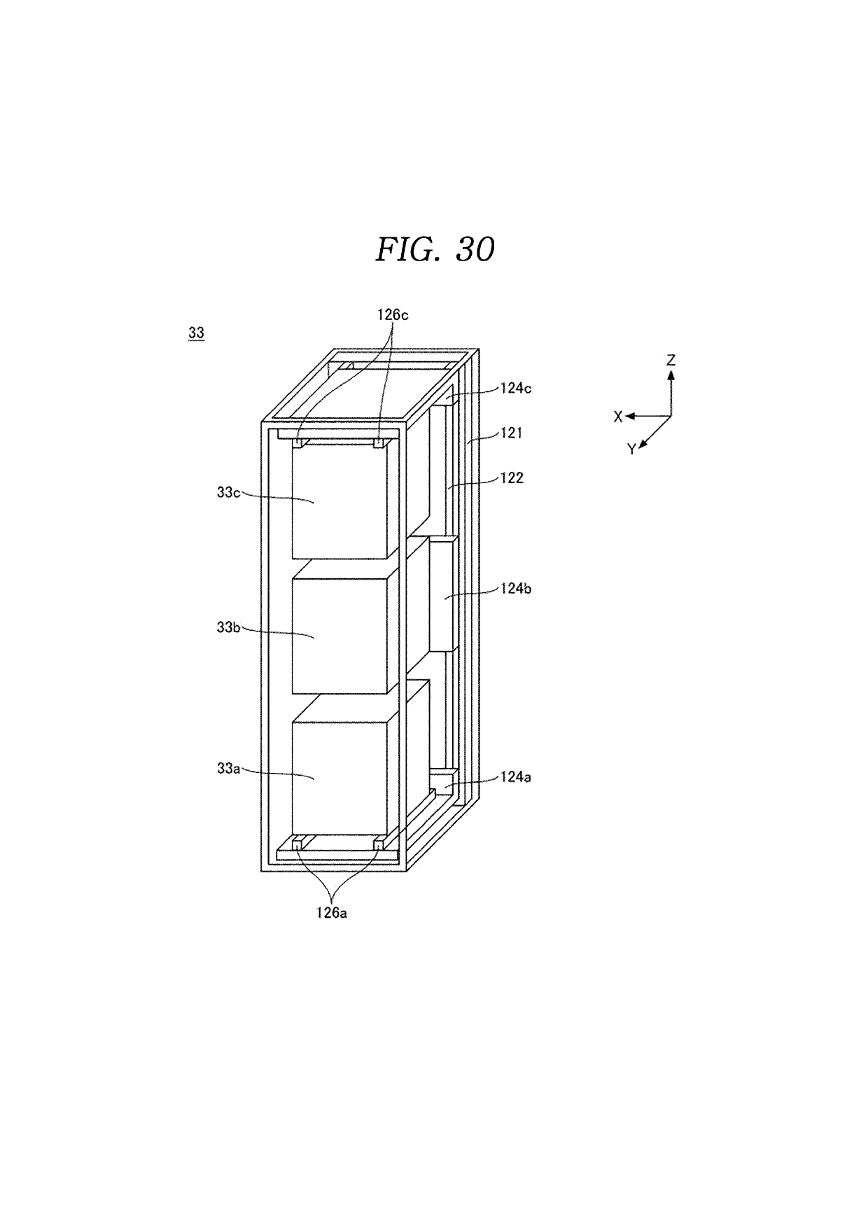

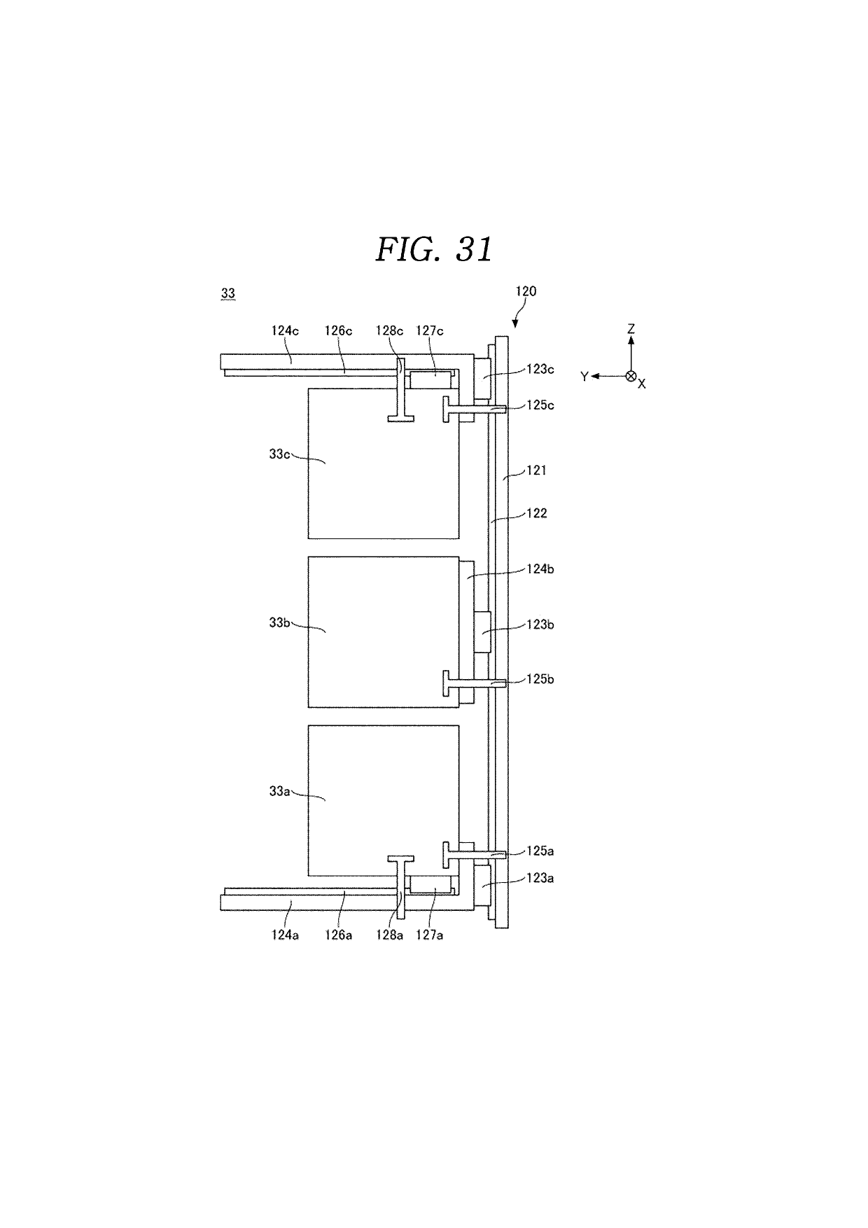

Referring to FIG. 29 to FIG. 31, a substrate processing apparatus 1D according to a fourth modification example of the exemplary embodiment will be explained. FIG. 29 is a plan view of the substrate processing apparatus 1D according to the fourth modification example of the exemplary embodiment. FIG. 30 is a perspective view illustrating the electrical equipment block 33. FIG. 31 is a side view illustrating the electrical equipment block 33.

In the fourth modification example, the electrical equipment block 33 is provided in the intermediate area 32m, as shown in FIG. 29. In this case, the overall height of the substrate processing apparatus 1D can be reduced.

In the fourth modification example, as shown in FIG. 30 and FIG. 31, the electrical equipment block 33 has three electrical equipment boxes 33a, 33b, and 33c stacked in multiple levels in the vertical direction. The respective electrical equipment boxes 33a, 33b, and 33c are configured to be movable independently of each other. In this case, a maintenance space can be secured for each of the levels.

The electrical equipment block 33 has the three electrical equipment boxes 33a, 33b and 33c, and a holder 120.

The electrical equipment boxes 33a, 33b, and 33c are provided at a lower level, an intermediate level, and an upper level, respectively. Each of the electrical equipment boxes 33a, 33b, and 33c is provided with: an electronic control device group that controls the operation of the drying device 32b of the lower level, the intermediate level, or the upper level; and a housing that accommodates the electronic control device group.

The holder 120 has a first base 121, a vertical guide rail 122, vertically moving members 123a, 123b and 123c, second bases 124a, 124b and 124c, vertically moving locks 125a, 125b and 125c, horizontal guide rails 126a and 126c, horizontally moving members 127a and 127c, and horizontally moving locks 128a and 128c.

The first base 121 is disposed at an end of the intermediate area 32m on the negative Y-axis side. The first base 121 extends from a top to a bottom of the processing station 3 along the vertical direction.

The vertical guide rail 122 is fixed to the first base 121. The vertical guide rail 122 extends from a top to a bottom of the first base 121 along the vertical direction. The vertical guide rail 122 may be, for example, an LM (Linear Motion) rail.

Each of the vertically moving members 123a, 123b, and 123c is configured to be movable in the vertical direction along the vertical guide rail 122. The vertically moving members 123a, 123b, and 123c are arranged in this order from below. The vertically moving members 123a, 123b, and 123c may be, for example, LM blocks.

The second base 124a has a vertical portion fixed to the vertically moving member 123a, and a horizontal portion that is bent into an L-shape at a lower end of the vertical portion to extend in the positive Y-axis direction. The second base 124b has a vertical portion fixed to the vertically moving member 123a. The electrical equipment box 33b is fixed to the second base 124b. The second base 124c has a vertical portion fixed to the vertically moving member 123c, and a horizontal portion that is bent into an L-shape at an upper end of the vertical portion to extend in the positive Y-axis direction.

The vertically moving locks 125a, 125b, and 125c are configured to lock movements of the second bases 124a, 124b, and 124c relative to the first base 121 along the vertical direction, respectively.

The horizontal guide rails 126a and 126c are fixed to the horizontal portions of the second bases 124a and 124c, respectively. The horizontal guide rails 126a and 126c extend along the Y-axis direction. The horizontal guide rails 126a and 126c may be, by way of example, LM rails.

The horizontally moving members 127a and 127c are configured to be movable in the Y-axis direction along the horizontal guide rails 126a and 126c, respectively. The electrical equipment boxes 33a and 33c are fixed to the horizontally moving members 127a and 127c, respectively. The horizontally moving members 127a and 127c may be, by way of non-limiting example, LM blocks.

The horizontally moving locks 128a and 128c are configured to lock movements of the electrical equipment boxes 33a and 33c relative to the second bases 124a and 124c along the Y-axis direction, respectively.

In this holder 120, the electrical equipment box 33a is elevated up and down by moving the vertically moving member 123a along the vertical guide rail 122, and is moved horizontally along the Y-axis direction by moving the horizontally moving member 127a along the horizontal guide rail 126a. The electrical equipment box 33b is elevated up and down by moving the vertically moving member 123b along the vertical guide rail 122. The electrical equipment box 33c is elevated up and down by moving the vertically moving member 123c along the vertical guide rail 122, and is moved horizontally along the Y-axis direction by moving the horizontally moving member 127c along the horizontal guide rail 126c.

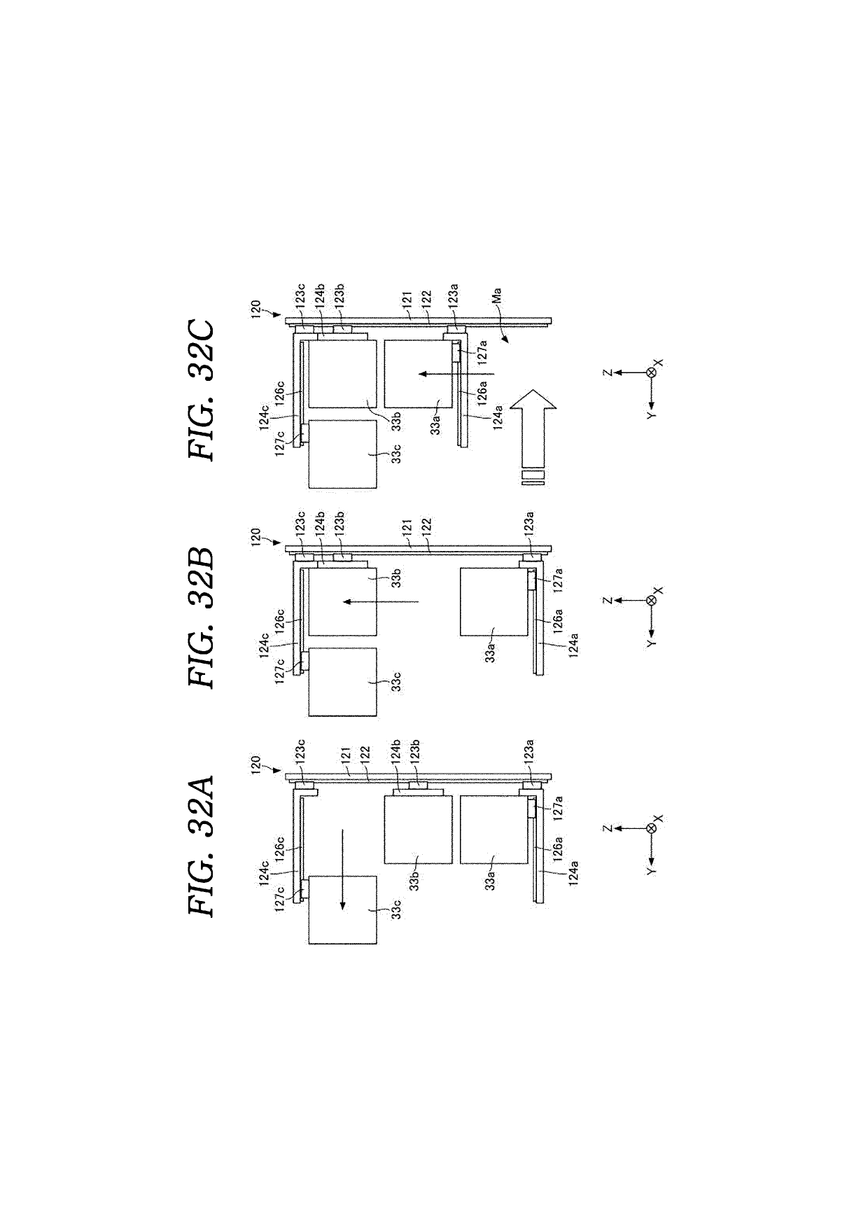

Referring to FIG. 32A to FIG. 32C, a method of performing the maintenance of the drying device 32b of the lower level will be described. FIG. 32A to FIG. 32C are side views illustrating movements of the electrical equipment block 33 during the maintenance of the lower level.

First, as shown in FIG. 32A, the worker P takes out the electrical equipment box 33c from the intermediate area 32m. Specifically, the worker P releases the fixation of the electrical equipment box 33c by the horizontally moving lock 128c, and moves the horizontally moving member 127c in the positive Y-axis direction along the horizontal guide rail 126c.

Then, as shown in FIG. 32B, the worker P raises the electrical equipment box 33b to the same height position as the drying device 32b of the upper level. Specifically, the worker P releases the fixation of the electrical equipment box 33b by the vertically moving lock 125b, and moves the vertically moving member 123b in the positive Z-axis direction along the vertical guide rail 122.

Thereafter, as illustrated in FIG. 32C, the worker P raises the electrical equipment box 33a to the same height position as the drying device 32b of the intermediate level. Specifically, the worker P releases the fixation of the electrical equipment box 33a by the vertically moving lock 125a, and moves the vertically moving member 123a in the positive Z-axis direction along the vertical guide rail 122.

Through the above-described operations, in the intermediate area 32m, a lower maintenance space Ma is formed at the same height position as the drying device 32b of the lower level. Thus, the worker P can enter the lower maintenance space Ma and perform the maintenance of the drying device 32b of the lower level.

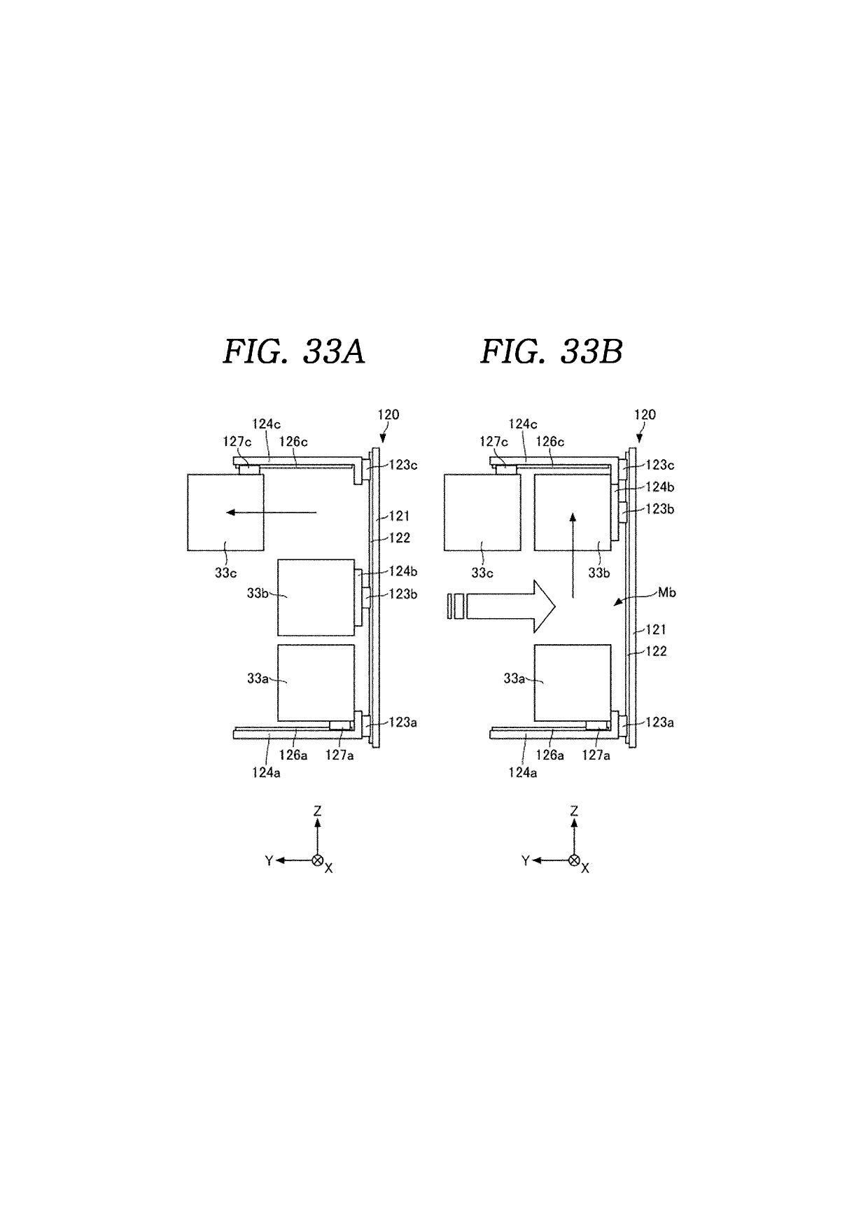

Referring to FIG. 33A and FIG. 33B, a method of performing the maintenance of the drying device 32b of the intermediate level will be described. FIG. 33A and FIG. 33B are side views illustrating movements of the electrical equipment block 33 during the maintenance of the intermediate level.

First, as shown in FIG. 33A, the worker P takes out the electrical equipment box 33c from the intermediate area 32m. Specifically, the worker P releases the fixation of the electrical equipment box 33c by the horizontally moving lock 128c, and moves the horizontally moving member 127c in the positive Y-axis direction along the horizontal guide rail 126c.

Subsequently, as illustrated in FIG. 33B, the worker P raises the electrical equipment box 33b to the same height position as the drying device 32b of the upper level. Specifically, the worker P releases the fixation of the electrical equipment box 33b by the vertically moving lock 125b, and moves the vertically moving member 123b in the positive Z-axis direction along the vertical guide rail 122.

Through the above-described operations, in the intermediate area 32m, an intermediate maintenance space Mb is formed at the same height position as the drying device 32b of the intermediate level. Thus, the worker P can enter the intermediate maintenance space Mb and perform the maintenance of the drying device 32b of the intermediate level.

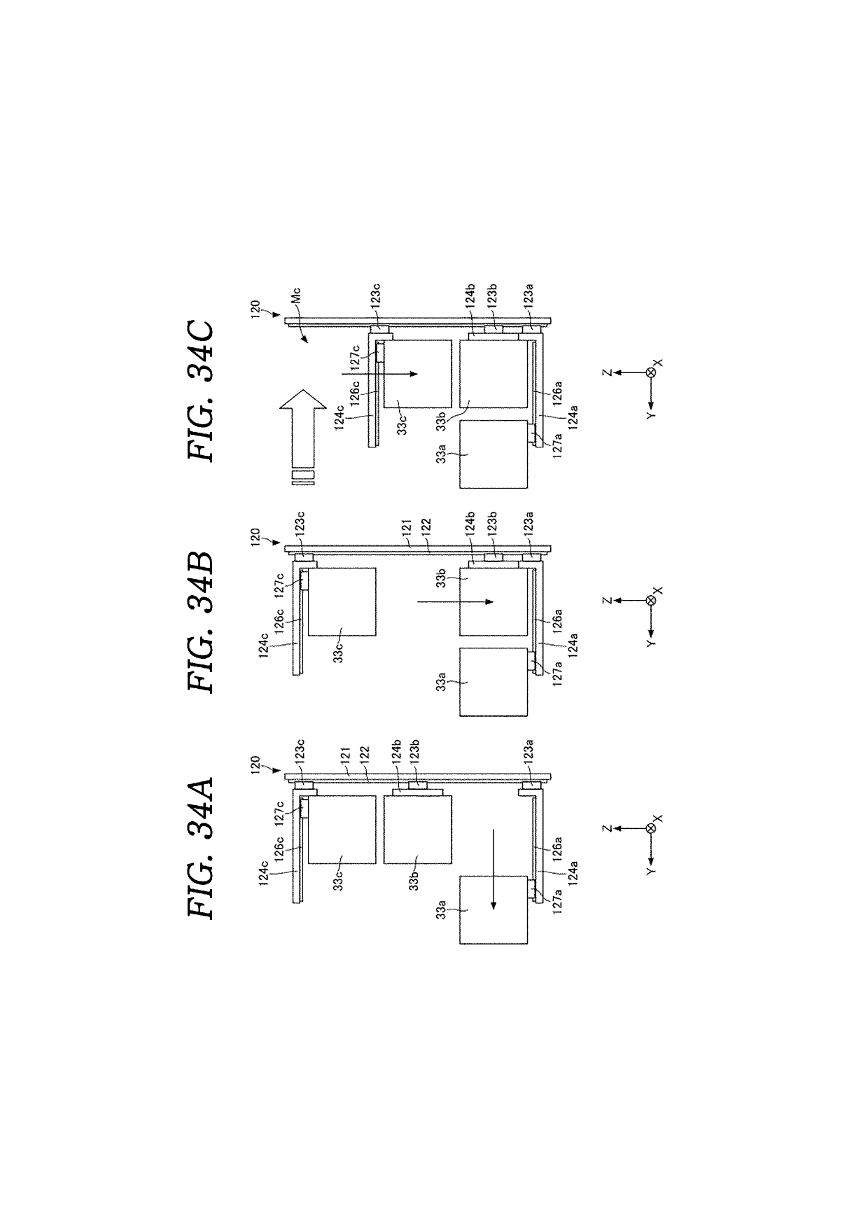

Referring to FIG. 34A to FIG. 34C, a method of performing the maintenance of the drying device 32b of the upper level will be described. FIG. 34A to FIG. 34C are side views illustrating movements of the electrical equipment block 33 during the maintenance of the upper level.

First, as shown in FIG. 34A, the worker P takes out the electrical equipment box 33a from the intermediate area 32m. Specifically, the worker P releases the fixation of the electrical equipment box 33a by the horizontally moving lock 128a, and moves the horizontally moving member 127a in the positive Y-axis direction along the horizontal guide rail 126a.

Then, as shown in FIG. 34B, the worker P lowers the electrical equipment box 33b to the same height position as the drying device 32b of the lower level. Specifically, the worker P releases the fixation of the electrical equipment box 33b by the vertically moving lock 125b, and moves the vertically moving member 123b in the negative Z-axis direction along the vertical guide rail 122.

Subsequently, as shown in FIG. 34C, the worker P lowers the electrical equipment box 33c to the same height as the drying device 32b of the intermediate level. Specifically, the worker P releases the fixation of the electrical equipment box 33c by the vertically moving lock 125c and moves the vertically moving member 123c to the negative side in the Z-axis direction along the vertical guide rail 122.

Through the above-described operations, in the intermediate area 32m, an upper maintenance space Mc is formed at the same height position as the drying device 32b of the upper level. Thus, the worker P can enter the upper maintenance space Mc and perform the maintenance of the drying device 32b of the upper level.

It should be noted that the above-described exemplary embodiment is illustrative in all aspects and is not anyway limiting. The above-described exemplary embodiment may be omitted, replaced and modified in various ways without departing from the scope and the spirit of claims.

The above exemplary embodiment has been descried for the case where the length of the transfer path of the substrate W is equal between the drying device 32b and each of the plurality of liquid film forming devices 32a included in the same unit block. However, the present disclosure is not limited thereto. For example, the second transfer device 31a may be configured to transfer the substrates W so that a transfer time of the substrates W is the same between the drying device 32b and each of the plurality of liquid film forming devices 32a belonging to the same unit block. In this case as well, the time taken until the liquid film formed on the top surface of the substrate W in each of the two liquid film forming devices 32a is replaced with the supercritical fluid in the drying device 32b can be made equal. As a result, the non-uniformity in the processing quality of the substrates W processed in the respective liquid film forming devices 32a can be reduced. The transfer time of the substrate W may be adjusted by, for example, controlling a moving speed of the second transfer device 31a. The transfer time of the substrate W may be adjusted by, for example, controlling a time period during which the substrate W stands by in the liquid film forming device 32a or a time period during which the second transfer device 31a is stopped in the state it is holding the substrate W after the liquid film is formed on the top surface of the substrate W.

According to the exemplary embodiments, it is possible to reduce the non-uniformity in processing between the substrates.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

The claims of the present application are different and possibly, at least in some aspects, broader in scope than the claims pursued in the parent application. To the extent any prior amendments or characterizations of the scope of any claim or cited document made during prosecution of the parent could be construed as a disclaimer of any subject matter supported by the present disclosure, Applicants hereby rescind and retract such disclaimer. Accordingly, the references previously presented in the parent applications may need to be revisited.

1. A substrate processing apparatus, comprising:
a plurality of unit blocks each including one or more liquid film forming devices each configured to form a liquid film on a top surface of a substrate, and a drying device configured to replace the liquid film with a supercritical fluid to dry the substrate;
a transfer block disposed adjacent to the plurality of unit blocks and including a transfer device configured to transfer the substrate between the liquid film forming devices and the drying device; and
an electrical equipment block disposed in an intermediate area between two drying devices of adjacent unit blocks, the electrical equipment block including a plurality of electrical equipment boxes stacked in a vertical direction, each of the electrical equipment boxes including an electronic control device configured to control an operation of at least one drying device,
wherein each of the plurality of electrical equipment boxes is movable independently of the other electrical equipment boxes so as to form, at each vertical level, a maintenance space aligned with a corresponding drying device.

2. The substrate processing apparatus of claim 1,
wherein the electrical equipment block further includes a holder assembly including a vertical guide rail fixed to a base and vertically moving members disposed along the vertical guide rail and each movable in the vertical direction, and
each of the vertically moving members supports a corresponding one of the electrical equipment boxes such that the corresponding electrical equipment box is movable in the vertical direction along the vertical guide rail.

3. The substrate processing apparatus of claim 2,
wherein the holder assembly includes a horizontal guide rail fixed to a horizontal portion of the base, and
at least one of the electrical equipment boxes is attached to a horizontally moving member that is movable along the horizontal guide rail in a direction away from the transfer block.

4. The substrate processing apparatus of claim 3,
wherein the electrical equipment box provided on the horizontally moving member is lockable at a retracted position by a horizontal moving lock.

5. The substrate processing apparatus of claim 1,
wherein each of the electrical equipment boxes is configured to be independently locked and unlocked relative to the other electrical equipment boxes to enable selective vertical and/or horizontal movement.

6. The substrate processing apparatus of claim 1,
wherein movement of one or more of the electrical equipment boxes forms, in the intermediate area, a maintenance space corresponding to a height of a corresponding one of a lower-level drying device, an intermediate-level drying device, or an upper-level drying device, and
the maintenance space is large enough to allow a worker to enter and perform maintenance of the corresponding drying device.

7. The substrate processing apparatus of claim 1,
wherein at least one of the electrical equipment boxes includes a horizontal portion extending in a positive Y-axis direction and bent in an L-shape from a vertical portion fixed to a vertically moving member.

8. The substrate processing apparatus of claim 1,
wherein a plurality of the transfer blocks are stacked in the vertical direction, each of the transfer blocks including the transfer device, and
the plurality of unit blocks are stacked in the vertical direction together with corresponding ones of the transfer blocks.

9. The substrate processing apparatus of claim 1,
wherein an inspecting device is stacked in the vertical direction with the drying device, and
the electrical equipment boxes are configured to control operation of the inspecting device in addition to the drying device.

10. A substrate processing apparatus, comprising:
a transfer block including a transfer device configured to transfer a substrate along a transfer path; and
a plurality of processing blocks arranged on both sides of the transfer block,
wherein each of the processing blocks includes a plurality of liquid film forming devices on one side of the transfer block and at least one drying device on an opposite side of the transfer block, and
wherein the at least one drying device is movable in a direction away from the transfer block and rotatable about a substantially vertical axis between an operating position and a service position to facilitate maintenance access.

11. The substrate processing apparatus of claim 10,
wherein, by rotation of the drying device, a substrate carry-in/carry-out surface of the drying device faces away from the transfer block, such that a worker is able to perform maintenance without entering an intermediate area.

12. The substrate processing apparatus of claim 10,
wherein the at least one drying device is mounted on a traveling mechanism that allows lateral displacement relative to the transfer block.

13. A method of maintaining a drying device in a substrate processing apparatus including an electrical equipment block having a plurality of electrical equipment boxes stacked in a vertical direction, the method comprising:
selecting at least one electrical equipment box corresponding to a vertical level of a target drying device;
unlocking the selected electrical equipment box; and
moving the selected electrical equipment box relative to the electrical equipment block to form, at the vertical level of the target drying device, a maintenance space that is large enough to allow a worker to access and perform maintenance of the target drying device.

14. The method of claim 13,
wherein moving the selected electrical equipment box includes moving the selected electrical equipment box vertically and horizontally to place the selected electrical equipment box at a position that does not obstruct the target drying device.

15. The method of claim 13,
wherein one or more other electrical equipment boxes are retracted to form a maintenance space at another vertical level, thereby enabling sequential maintenance of drying devices arranged at a plurality of vertical levels.
